(19) United States
(12) Patent Application Publication
(10) Pub. No.: US 2023/0282663 A1
(43) Pub. Date: Sep. 7, 2023

(54) IMAGE SENSOR

(71) Applicant: Samsung Electronics Co., Ltd., Suwon-si (KR)

(72) Inventors: Jehyung Ryu, Suwon-si (KR); Hajin Lim, Seoul (KR); Taeksoo Jeon, Hwaseong-si (KR)

(21) Appl. No.: 18/100,216

(22) Filed: Jan. 23, 2023

(30) Foreign Application Priority Data
Jan. 28, 2022 (KR) 10-2022-0013619

(51) Int. Cl. H01L 27/146

(52) U.S. Cl. CPC H01L 27/14625; H01L 27/14645

(57) ABSTRACT

An image sensor includes a first pixel and a second pixel disposed adjacent to the first pixel. A pixel separation structure is disposed between the first pixel and the second pixel. A rear anti-reflection layer is disposed on the first pixel, the second pixel, and the pixel separation structure. A fence structure is disposed on the rear anti-reflection layer and positioned to overlap the pixel separation structure in a plan view. The fence structure includes a barrier metal layer and a fence. A height of the barrier metal layer is less than a height of the fence. A width of the barrier metal layer is less than a width of the fence.

### CROSS-REFERENCE TO RELATED APPLICATION

This application claims priority under 35 U.S.C. §119 to Korean Patent Application No. 10-2022-0013619, filed on Jan. 28, 2022 in the Korean Intellectual Property Office, the disclosure of which is incorporated by reference in its entirety herein.

### 1 Technical Field

The present inventive concept relates to an image sensor, and more particularly, to a complementary metal-oxide semiconductor (CMOS) image sensor.

### 2 Discussion of Related Art

An image sensor is an electronic device that captures an image and converts the image into an electrical signal. An image sensor may be, for example, a CMOS image sensor, which may be applied in consumer electronic devices, such as digital cameras, mobile phone cameras, and portable camcorders, as well as cameras mounted on automobiles, security devices, and robots.

As the size of image sensors is continually decreasing, the size of the pixels is also decreasing However, image sensors with a relatively small size should still effectively reduce crosstalk between pixels and provide an increased sensitivity.

### SUMMARY

Embodiments of the present inventive concept provide an image sensor capable of reducing crosstalk between pixels and increasing sensitivity

According to an aspect of the present inventive concept, an image sensor includes a first pixel and a second pixel disposed adjacent to the first pixel. A pixel separation structure is disposed between the first pixel and the second pixel. A rear anti-reflection layer is disposed on the first pixel, the second pixel, and the pixel separation structure. A fence structure is disposed on the rear anti-reflection layer and positioned to overlap the pixel separation structure in a plan view. The fence structure includes a barrier metal layer and a fence. A height of the barrier metal layer is less than a height of the fence. A width of the barrier metal layer is less than a width of the fence.

According to an embodiment of the present inventive concept, an image sensor includes a first pixel. A second pixel is disposed adjacent to the first pixel. A pixel separation structure is disposed between the first pixel and the second pixel. A rear anti-reflection layer is disposed on the first pixel, the second pixel, and the pixel separation structure. A fence structure is disposed on the rear anti-reflection layer and is positioned to overlap the pixel separation structure in a plan view. A color filter is disposed at both sides of the fence structure on the rear anti-reflection layer. The fence structure includes a barrier metal layer disposed on the rear anti-reflection layer and a fence disposed on the barrier metal layer. A height of the barrier metal layer is less than a height of the fence. A width of the barrier metal layer is less than a width of the fence The color filter is buried in an undercut portion recessed inward from both side walls of the fence in a lower portion of the fence.

According to an embodiment of the present inventive concept, an image sensor includes a first pixel. A second pixel is disposed adjacent to the first pixel. A pixel separation structure is disposed between the first pixel and the second pixel. A rear anti-reflection layer is disposed on the first pixel, the second pixel, and the pixel separation structure. A fence structure is disposed on the rear anti-reflection layer and positioned to overlap the pixel separation structure in a plan view. A color filter is disposed at both sides of the fence structure on the rear anti-reflection layer. The fence structure comprises a barrier metal layer disposed on the rear anti-reflection layer and a fence disposed on the barrier metal layer. A height of the barrier metal layer is less than a height of the fence. A width of the barrier metal layer is less than a width of the fence. The barrier metal layer is buried in the fence.

### BRIEF DESCRIPTION OF THE DRAWINGS

Embodiments of the present inventive concept will be more clearly understood from the following detailed description taken in conjunction with the accompanying drawings in which:

FIG. 1A is a schematic circuit diagram of an image sensor according to an embodiment of the present inventive concept;

FIG. 1B is a layout diagram of a pixel array region of the image sensor of FIG. 1A according to an embodiment of the present inventive concept;

FIG. 2 is a circuit diagram of a pixel included in an image sensor according to an embodiment of the present inventive concept;

FIG. 3 is a plan view of an image sensor according to an embodiment of the present inventive concept;

FIG. 4 is a cross-sectional view of an image sensor taken along line A-A′ of FIG. 3 according to an embodiment of the present inventive concept;

FIG. 5 is an enlarged view of a region EL1 of FIG. 4 according to an embodiment of the present inventive concept;

FIGS. 6A and 6B are plan views illustrating fence structures of image sensors according to embodiments of the present inventive concept;

FIG. 7 is a plan view illustrating a fence structure of an image sensor according to an embodiment of the present inventive concept;

FIG. 8 is a cross-sectional view of an image sensor taken along line A-A′ of FIG. 3 according to an embodiment of the present inventive concept;

FIG. 9 is an enlarged view of a region EL2 of FIG. 8 according to an embodiment of the present inventive concept;

FIG. 10 is a plan view illustrating a fence structure of an image sensor according to an embodiment of the present inventive concept;

FIG. 11 is a plan view illustrating a fence structure of an image sensor according to an embodiment of the present inventive concept;

FIG. 12 is a cross-sectional view of an image sensor taken along line A-A′ of FIG. 3 according to an embodiment of the present inventive concept;

FIG. 13 is an enlarged view of a region EL3 of FIG. 12;

FIG. 14 is a cross-sectional view of an image sensor taken along line A-A′ of FIG. 3 according to an embodiment of the present inventive concept;

FIG. 15 is an enlarged view of a region EL4 of FIG. 14 according to an embodiment of the present inventive concept;

FIG. 16 is a plan view of a pixel of an image sensor according to an embodiment of the present inventive concept;

FIG. 17 is a plan view of a pixel of an image sensor according to an embodiment of the present inventive concept;

FIGS. 18A to 18E are cross-sectional views illustrating a method of manufacturing a fence structure of an image sensor, according to embodiments of the present inventive concept;

FIGS. 19A and 19B are cross-sectional views illustrating a method of manufacturing a fence structure of an image sensor, according to embodiments of the present inventive concept;

FIGS. 20A to 20F are cross-sectional views illustrating a method of manufacturing a fence structure of an image sensor, according to embodiments of the present inventive concept;

FIGS. 21A and 21B are cross-sectional views illustrating a method of manufacturing a fence structure of an image sensor, according to embodiments of the present inventive concept;

FIG. 22 is a block diagram illustrating a configuration of an image sensor, according to an embodiment of the present inventive concept;

FIG. 23 is a configuration diagram of a camera using an image sensor according to an embodiment of the present inventive concept; and

FIG. 24 is a block diagram of an imaging system including an image sensor according to an embodiment of the present inventive concept.

### DETAILED DESCRIPTION OF EMBODIMENTS

Hereinafter, embodiments of the present inventive concept will be described in detail with reference to the accompanying drawings. The following embodiments of the present inventive concept may be implemented by only one embodiment, and also, the following embodiments may be implemented by combining one or more embodiments. Therefore, the technical spirit of the present inventive concept is not construed as being limited to one embodiment.

Also, in the present specification, the singular form of the elements may include the plural form unless the context clearly indicates otherwise. In the present specification, the drawings may be exaggerated to provide clearly explain embodiments of the present inventive concept.

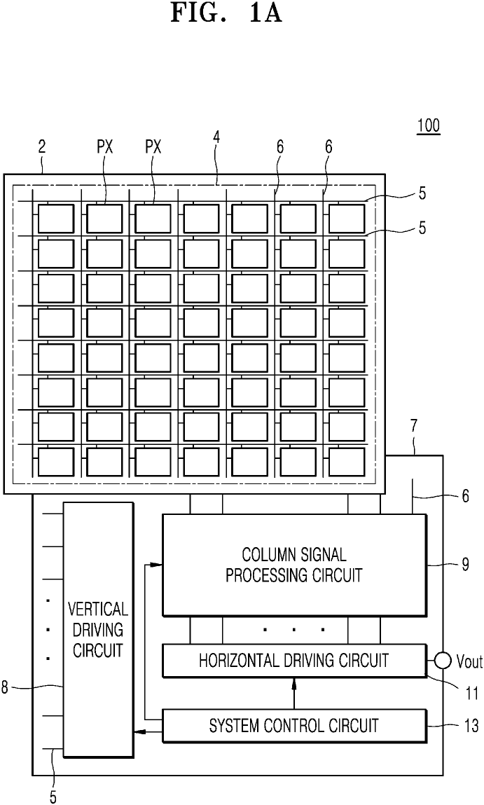

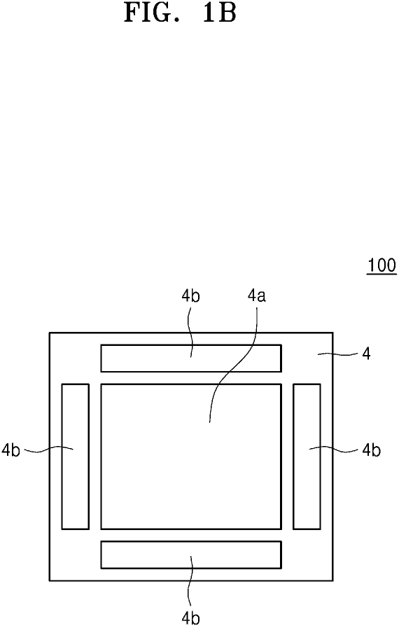

FIG. 1A is a schematic circuit diagram of an image sensor 100 according to an embodiment of the present inventive concept, and FIG. 1B is a layout diagram of a pixel array region 4 of the image sensor 100 of FIG. 1A.

In an embodiment, the image sensor 100 may be applied to a stacked image sensor including a first substrate 2 and a second substrate 7. For example, the image sensor 100 may be a complementary metal-oxide semiconductor (CMOS) image sensor. The technical idea of the present inventive concept described below may be mainly applied to the first substrate 2.

The image sensor 100 may include the first substrate 2 and the second substrate 7. The image sensor 100 may be configured by stacking and bonding the first substrate 2 on the second substrate 7. The first substrate 2 may be a sensor substrate including a pixel circuit. The second substrate 7 may be a support substrate on which a logic circuit for driving the pixel circuit is formed. The second substrate 7 may support the first substrate 2. The first substrate 2 and the second substrate 7 may be electrically connected to each other.

In an embodiment, the pixel array region 4, in which unit pixels PX (or unit pixels) including a photoelectric conversion region are regularly two-dimensionally arranged on the first substrate 2, is provided. In the pixel array region 4, pixel driving lines 5 are wired in a row direction and vertical signal lines 6 are wired in a column direction.

In an embodiment, one unit pixel PX is arranged to be connected to one pixel driving line 5 and one vertical signal line 6. In each unit pixel PX, a pixel circuit including a photoelectric converter, a charge accumulator, and transistors, such as a metal oxide semiconductor (MOS) transistor, and/or a capacitor may be provided.

In addition, as shown in FIG. 1B, the pixel array region 4 may include an active pixel block 4a, in which the unit pixel PX is formed, and an optical black block 4b for detecting a dark current of the unit pixel PX around the active pixel block 4a.

In the second substrate 7, a logic circuit, such as a vertical driving circuit 8 for driving each unit pixel PX provided on the first substrate 2, a column signal processing circuit 9, a horizontal driving circuit 11, and a system control circuit 13 may be provided. The image sensor 100 may output a voltage Vout (output voltage) through the horizontal driving circuit 11.

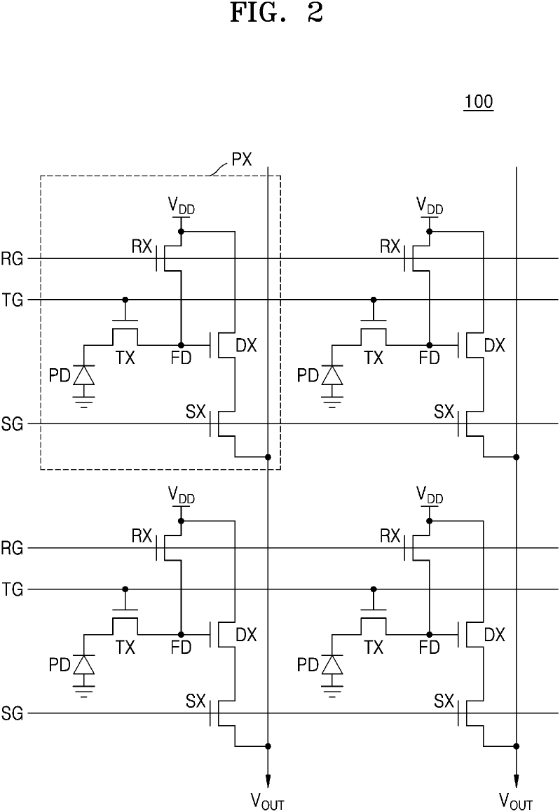

FIG. 2 is a circuit diagram of a pixel PX included in the image sensor 100 according to an embodiment of the present inventive concept.

In an embodiment, in the image sensor 100, a plurality of pixels PX may be arranged in a matrix form or an array form. Each of the plurality of pixels PX may include a transfer transistor TX and logic transistors.

The logic transistors may include a reset transistor RX, a selection transistor SX, and a drive transistor DX (e.g., a source follower transistor). The reset transistor RX may include a reset gate RG, the selection transistor SX may include a selection gate SG, and the transfer transistor TX may include a transfer gate TG.

Each of the plurality of pixels PX may include a photoelectric conversion element PD and a floating diffusion region FD. The photoelectric conversion element PD may correspond to a photoelectric conversion region described below. The photoelectric conversion element PD may generate and accumulate photocharges in proportion to an amount of incident external light, and a photodiode, a phototransistor, a photogate, and a pinned photodiode (PPD), and combinations thereof may be used.

The transfer transistor TX may be operated by a transfer control signal transmitted to the transfer gate TG. The transfer gate TG may transfer charges generated by the photoelectric conversion element PD to the floating diffusion region FD. The floating diffusion region FD may receive and accumulate charges generated by the photoelectric conversion element PD. Charges generated by the photoelectric conversion element PD may be transferred to and accumulated in the floating diffusion region FD by the transfer transistor TX. The drive transistor DX may be controlled according to an amount of photocharges accumulated in the floating diffusion region FD.

The reset transistor RX may periodically reset charges accumulated in the floating diffusion region FD. The reset transistor RX may be operated by a reset control signal transmitted through the reset gate RG. A drain electrode of the reset transistor RX is connected to the floating diffusion region FD, and a source electrode of the reset transistor RX is connected to a power supply voltage VDD.

When the reset transistor RX is turned on by the reset control signal, the power supply voltage VDD connected to the source electrode of the reset transistor RX is transferred to the floating diffusion region FD. When the reset transistor RX is turned on, charges accumulated in the floating diffusion region FD may be discharged to reset the floating diffusion region FD. The reset transistor RX may reset the voltage of the floating diffusion region FD to the power supply voltage VDD.

In an embodiment, the drive transistor DX is connected to a current source located outside the plurality of pixels PX and functions as a source follower buffer amplifier. The drive transistor DX may amplify charges accumulated in the floating diffusion region FD and transfer the charges to the selection transistor SX. The drive transistor DX amplifies a potential change in the floating diffusion region FD and outputs the potential change as an output voltage Vout.

The selection transistor SX may select the plurality of pixels PX in a row unit. The selection transistor SX may select a unit pixel by a selection control signal transferred to the selection gate SG. When the selection transistor SX is turned on, the power supply voltage VDD may be transferred to a source electrode of the selection transistor SX. The selection transistor SX may be operated by the selection control signal, and may perform switching and addressing operations. When the selection control signal is applied to the selection transistor SX, the selection transistor SX may output the output voltage Vout connected to the unit pixel.

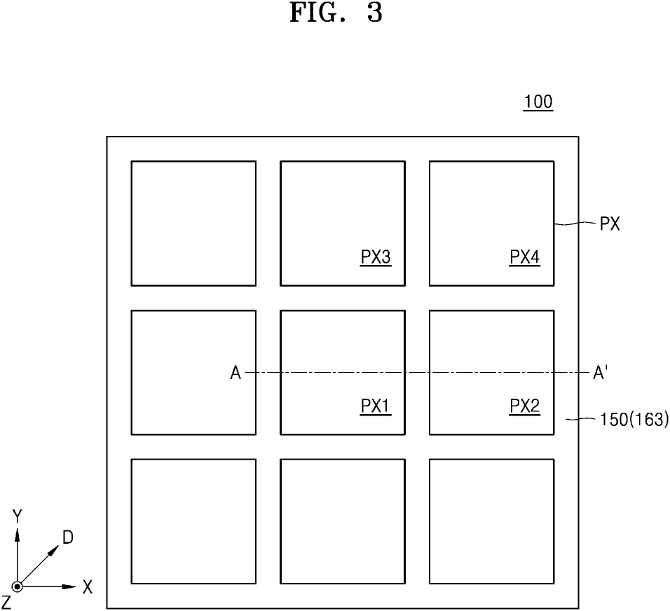

FIG. 3 is a plan view of the image sensor 100 according to an embodiment of the present inventive concept.

In an embodiment, the image sensor 100 may include the plurality of pixels PX. The pixel PX may include at least one photoelectric conversion element. The plurality of pixels PX may be two-dimensionally arranged. For example, a second pixel PX2 may be spaced apart from a first pixel PX1 in a first direction (X direction), and a third pixel PX3 may be spaced apart from the first pixel PX1 in a second direction (Y direction).

A fourth pixel PX4 may be spaced apart from the first pixel PX1 in a diagonal direction (D direction), may be spaced apart from the second pixel PX2 in the second direction (Y direction), and may be spaced apart from the third pixel PX3 in the first direction (X direction).

In some embodiments, the first direction (X direction) may be perpendicular to the second direction (Y direction). However, embodiments of the present inventive concept are not necessarily limited thereto. In some embodiments, the diagonal direction (D direction) may be oblique with respect to the first direction (X direction) and the second direction (Y direction). In some embodiments, the diagonal direction (D direction) may form 45 degrees with the first direction (X direction) and the second direction (Y direction). However, embodiments of the present inventive concept are not necessarily limited thereto. For example, in an embodiment, the diagonal direction (D direction) may form another angle with the first direction (X direction) and the second direction (Y direction).

A pixel separation structure 150 may be located between the plurality of pixels PX. The pixel separation structure 150 may physically and electrically separate one pixel PX from the adjacent pixel PX, such as the first pixel PX1 from the second pixel PX2. In an embodiment, the pixel separation structure 150 may be arranged in a mesh shape or a grid shape in a plan view (e.g., in a plane defined in the X and Y directions). In some embodiments, the pixel separation structure 150 may extend between the plurality of pixels PX. For example, the pixel separation structure 150 may extend between the first pixel PX1 and the second pixel PX2, between the first pixel PX1 and the third pixel PX3, between the second pixel PX2 and the fourth pixel PX4, and between the third pixel PX3 and the fourth pixel PX4.

A fence structure 163 may be disposed on the pixel separation structure 150. The fence structure 163 may overlap the pixel separation structure 150 in the plan view The fence structure 163 may extend between the pixels PX in the plan view. For example, in the plan view, the fence structure 163 may extend between the first pixel PX1 and the second pixel PX2, between the first pixel PX1 and the third pixel PX3, between the second pixel PX2 and between the fourth pixel PX4, and between the third pixel PX3 and the fourth pixel PX4. The fence structure 163 is described in more detail below.

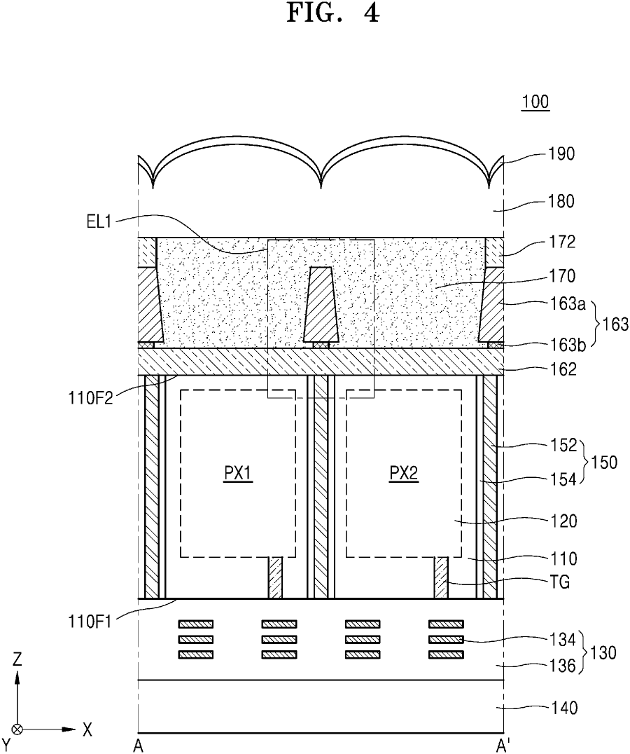

FIG. 4 is a cross-sectional view of the image sensor 100 according to an embodiment of the present inventive concept.

FIG. 4 may be a cross-sectional view of the image sensor 100 taken along line A-A′ of FIG. 3. The image sensor 100 may include a substrate 110, a photoelectric conversion region 120, the transfer gate TG, the pixel separation structure 150, a front structure 130, a support substrate 140, a rear anti-reflection layer 162, the fence structure 163, a passivation layer 172, a color filter 170, a microlens 180, and a capping layer 190.

The substrate 110 may include a first surface 110F1 and a second surface 110F2. In an embodiment, the first surface 110F1 may be a front surface of the substrate 110. The second surface 110F2 may be a rear surface of the substrate 110. In some embodiments, the substrate 110 may include a semiconductor material, such as a group IV semiconductor material, a group III-V semiconductor material, or a group II-VI semiconductor material.

In an embodiment, the group IV semiconductor material may include silicon (Si), germanium (Ge), or silicon (Si)-germanium (Ge). The group III-V semiconductor material may include gallium arsenide (GaAs), indium phosphate (InP), gallium phosphate (GaP), indium arsenide (InAs), indium antimony (InSb), or indium gallium arsenide (InGaAs). The group II-VI semiconductor material may include zinc telluride (ZnTe) or cadmium sulfide (CdS).

The substrate 110 may include a P type semiconductor substrate. In some embodiments, the substrate 110 may be configured as a P type silicon substrate. In some embodiments, the substrate 110 may include a P type bulk substrate and a P type or N type epitaxial layer grown thereon. In some embodiments, the substrate 110 may include an N type bulk substrate and a P type or N type epitaxial layer grown thereon.

The photoelectric conversion region 120 may be disposed in the substrate 110. The photoelectric conversion region 120 may convert an optical signal into an electrical signal. In an embodiment, the photoelectric conversion region 120 may include a photodiode region and a well region formed inside the substrate 110. The photoelectric conversion region 120 may be an impurity region doped with impurities of a conductivity type opposite to that of the substrate 110.

The transfer gate TG may be disposed in the substrate 110. The transfer gate TG may extend into the substrate 110 from the first surface 110F1 of the substrate 110. The transfer gate TG may be a part of the transfer transistor (TX in FIG. 2). The transfer transistor TX, the reset transistor RX, the drive transistor DX, and the selection transistor SX described above with reference to FIG. 2 may be formed on the first surface 110F1 of the substrate 110.

In an embodiment, a device isolation layer defining an active region and the floating diffusion region FD may be further formed on the first surface 110F1 of the substrate 110 The photoelectric conversion region 120, the transfer gate TG, the plurality of transistors, and the floating diffusion region FD may constitute the pixel PX described above with reference to FIG. 3.

The pixel separation structure 150 may penetrate the substrate 110, and physically and electrically separate one pixel PX from an adjacent pixel PX, for example, the first pixel PX1 from the second pixel PX2. The pixel separation structure 150 may extend from the first surface 110F1 to the second surface 11 0F2 of the substrate 110.

In some embodiments, the pixel separation structure 150 may include a conductive layer 152 and an insulating liner 154. Each of the conductive layer 152 and the insulating liner 154 may penetrate the substrate 110 from the first surface 110F1 to the second surface 110F2 of the substrate 110. The insulating liner 154 may be disposed between the substrate 110 and the conductive layer 152 (e.g., in the X direction) to electrically separate the conductive layer 152 from the substrate 110.

In some embodiments, the conductive layer 152 may include a conductive material, such as polysilicon or metal. The insulating liner 154 may include a metal oxide, such as hafnium oxide, aluminum oxide, tantalum oxide, etc. In an embodiment, the insulating liner 154 may act as a negative fixed charge layer. However, embodiments of the present inventive concept are not necessarily limited thereto. For example, in some embodiments, the insulating liner 154 may include an insulating material, such as silicon oxide, silicon nitride, or silicon oxynitride.

The front structure 130 may be disposed on the first surface 110F1 of the substrate 110. The front structure 130 may include a wiring layer 134 and an insulating layer 136. The insulating layer 136 may electrically separate the wiring layer 134 below the first surface 110F1 of the substrate 110.

The wiring layer 134 may be electrically connected to a transistor on the first surface 110F1 of the substrate 110. In an embodiment, the wiring layer 134 may include tungsten, aluminum, copper, tungsten silicide, titanium silicide, tungsten nitride, titanium nitride, doped polysilicon, etc. The insulating layer 136 may include an insulating material, such as silicon oxide, silicon nitride, silicon oxynitride, or a low-k material.

In an embodiment, the low-k material may include at least one of, for example, flowable oxide (FOX), Torene SilaZene (TOSZ), undoped silica glass (USG), Borosilicate glass (BSG), PhosphoSilicate glass (PSG), BoroPhosphoSilicate glass (BPSG), plasma enhanced tetra ethyl ortho silicate (PETEOS), fluoride silicate glass (FSG), carbon doped silicon oxide (CDO), xerogel, aerogel, amorphous fluorinated carbon, organo silicate glass (OSG), parylene, bis-benzocyclobutenes (BCB), SiLK, polyimide, a porous polymeric material, or combinations thereof. However, embodiments of the present inventive concept are not necessarily limited thereto. In an embodiment, the support substrate 140 may be disposed on the front structure 130.

In an embodiment, an adhesive member may be further disposed between the support substrate 140 and the front structure 130. The support substrate 140 may correspond to the second substrate 7 of FIG. 1. The support substrate 140 may include a logic circuit for driving a pixel circuit, and may be a support substrate that supports the substrate 110.

The rear anti-reflection layer 162 may be disposed on the second surface 110F2 of the substrate 110. The rear anti-reflection layer 162 may be disposed on all the pixels PX and the pixel separation structure 150.

In some embodiments, the rear anti-reflection layer 162 may include hafnium oxide (HfO₂), silicon nitride (SiN), aluminum oxide (Al₂O₃), zirconium oxide (ZrO₂), tantalum oxide (Ta₂O₅), titanium oxide (TiO₂), lanthanum oxide (La₂O₃), praseodymium oxide (Pr₂O₃), cerium oxide (CeO₂), neodymium oxide (Nd₂O₃), promethium oxide (Pm₂O₂), samarium oxide (Sm₂O₃), europium oxide (Eu₂O₃), gadolinium oxide (Gd₂O₃), terbium oxide (Tb₂O₃), dysprosium oxide (Dy₂O₃), holmium oxide (H_{O2}O₃), thulium oxide (Tm₂O₃), ytterbium oxide (Yb₂O₃), lutetium oxide (Lu₂O₃), or yttrium oxide (Y₂O₃). In some embodiments, the rear anti-reflection layer 162 may be a single layer including any one of the materials described above or a multi-layer in which layers of the materials described above are stacked.

In some embodiments, the fence structure 163 may include a fence 163a and a barrier metal layer 163b located below the fence 163a. For example, the barrier metal layer 163b may be disposed directly on the rear anti-reflection layer 162. The fence 163a may be an insulator fence. The fence structure 163 may be disposed on the rear anti-reflection layer 162. The fence structure 163 may be referred to as a grid. The fence structure 163 may overlap the pixel separation structure 150 in a plan view as described above.

In some embodiments, the fence 163a may include silicon oxide. In some embodiments, the fence 163a may include a low refractive index material. In an embodiment, the low refractive index material may have an index of refraction in a range of about 10 to about 1.4. In an embodiment, the low refractive index material may include polymethyl methacrylate (PMMA), silicon acrylate, cellulose acetate butyrate (CAB), silica, or fluoro-silicon acrylate (FSA). For example, the low refractive index material may include a polymer material in which silica (SiOx) particles are dispersed.

In an embodiment in which the fence 163a includes a low refractive index material having a relatively low refractive index, light incident toward the fence 163a may be totally reflected and directed toward the center of the first or second pixel PX1 or PX2. The fence 163a may prevent light that is incident obliquely into the color filter 170 disposed on one pixel, such as the first or second pixel PX1 or PX2, from entering into the color filter 170 disposed on the adjacent first or second pixel PX1 or PX2. Accordingly, the fence 163a may prevent crosstalk between the plurality of first and second pixels PX1 and PX2.

The barrier metal layer 163b may include a metal material, for example, TiN. The barrier metal layer 163b may be located at a lower portion of the fence structure 163 and may be disposed below the fence 163a. In an embodiment in which the barrier metal layer 163b is electrically connected to an optical black block, the image sensor 100 may reduce an electrostatic defect, for example, a bruising defect. Accordingly, the barrier metal layer 163b may be a metal layer for preventing the bruising defect. In an embodiment, the height of the barrier metal layer 163b may be lower than the height of the fence 163a.

The passivation layer 172 may be disposed on the fence structure 163. The passivation layer 172 may protect the fence structure 163. In some embodiments, the passivation layer 172 may include aluminum oxide. In some embodiments, the height (or thickness) of the passivation layer 172 may be in a range of about 5 nm to about 20 nm.

In some embodiments, a plurality of color filters 170 may be formed between the fence structures 163. In some embodiments, the plurality of color filters 170 may be separated from each other by the fence structure 163, unlike an embodiment shown in FIG. 4. In an embodiment, the plurality of color filters 170 may be a combination of a green filter, a blue filter, and a red filter. However, embodiments of the present inventive concept are not necessarily limited thereto and the colors of the plurality of color filters 170 may vary. For example, in some embodiments, the plurality of color filters 170 may be a combination of cyan, magenta, and yellow.

The microlens 180 may be disposed on the color filter 170 and the passivation layer 172. The microlens 180 may be disposed to correspond to the pixel PX. The microlens 180 may be transparent. In some embodiments, the microlens 180 may have a transmittance that is greater than or equal to about 90% with respect to light in a visible ray region. The light in the visible ray region may have a wavelength of about 380 nm to about 770 nm.

In some embodiments, the microlens 180 may include a resin-based material, such as a styrene-based resin, an acrylic resin, a styrene-acrylic copolymer-based resin, or a siloxane-based resin. The microlens 180 may collect incident light, and the collected light may be incident on the photoelectric conversion region 120 through the color filter 170. The capping layer 190 may be disposed on the microlens 180.

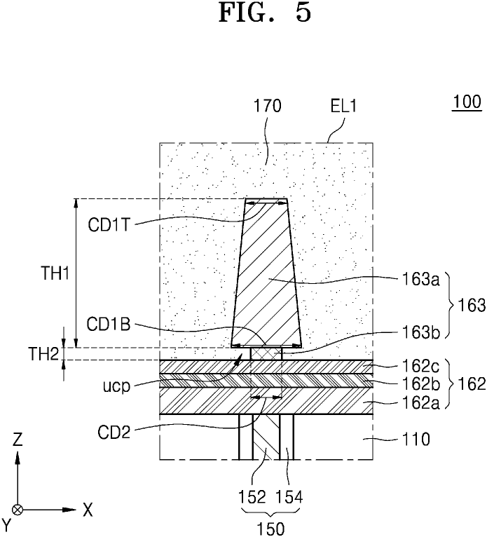

FIG. 5 is an enlarged view of a region EL1 of FIG. 4.

As shown in an embodiment of FIG. 5, the rear anti-reflection layer 162 may be formed on the substrate 110 and the pixel separation structure 150. In some embodiments, the thickness of the rear anti-reflection layer 162 may be in a range of about 50 nm to about 200 nm. In an embodiment, the rear anti-reflection layer 162 may include a plurality of sub rear anti-reflection layers, such as first to third sub rear anti-reflection layers 162a, 162b, and 162c. In an embodiment shown in FIG. 5, the rear anti-reflection layer 162 includes three layers, such as the first to third sub rear anti-reflection layers 162a, 162b, and 162c. However, embodiments of the present inventive concept are not necessarily limited thereto and the rear anti-reflection layer may have more or less than three layers.

The first to third sub rear anti-reflection layers 162a, 162b, and 162c may include a combination of materials constituting the rear anti-reflection layer 162 described above. The first to third sub rear anti-reflection layers 162a, 162b, and 162c may include a plurality of material layers having different thicknesses. In some embodiments, the first sub rear anti-reflection layer 162a may include aluminum oxide (Al₂O₃), the second sub rear anti-reflection layer 162b may include hafnium oxide, and the third sub rear anti-reflection layer 162c may include silicon oxide. However, embodiments of the present inventive concept are not necessarily limited thereto.

The fence structure 163 may be located on the rear anti-reflection layer 162 to correspond to or be aligned with the pixel separation structure 150 in a direction perpendicular to the substrate 110. As described above, the fence structure 163 may include the fence 163a and the barrier metal layer 163b located below the fence 163a.

The fence structure 163 may directly contact the rear anti-reflection layer 162. The fence 163a is provided to suppress crosstalk between the pixels (PX1 and PX2 in FIG. 4), as described above. In some embodiments, the fence 163a may include silicon oxide as described above. In some embodiments, the fence 163a may include a low refractive index material. The low-refractive-index material is described above, and thus a description thereof will be omitted for economy of description.

The fence 163a may have first widths CD1T and CD1B in a horizontal direction (e.g., the X direction) that is parallel to the upper surface of the rear anti-reflection layer 162. The first widths CD1T and CD1B may be referred to as first threshold sizes. The first widths CD1T and CD1B may include an upper width CD1T and a lower width CD1B.

In an embodiment, the first widths CD1T and CD1B may be several tens of nm, for example, the first widths CD1T and CD1B may be in a range of about 20 nm to about 80 nm. In some embodiments, the upper width CD1T may be less than the lower width CD1B. In some embodiments, unlike in FIG. 5, the upper width CD1T may be the same as the lower width CD1B. The upper width CD1T and the lower width CD1B may be referred to as an upper threshold size and a lower threshold size, respectively.

The fence 163a may have a first height TH1 in a vertical direction (e.g., the Z direction) perpendicular to an upper surface of the rear anti-reflection layer 162. In some embodiments, the first height TH1 of the fence 163a may be several hundred nm or less, for example, the first height TH1 of the fence 163a may be in a range of about 300 nm to about 500 nm. The fence 163a may be spaced apart from the rear anti-reflection layer 162 (e.g., in the Z direction which is a thickness direction of the image sensor 100) by the barrier metal layer 163b.

In an embodiment, the barrier metal layer 163b may be vertically disposed at a central portion of the fence 163a (e.g., in the X direction). The barrier metal layer 163b is provided to increase sensitivity by suppressing an electrostatic defect (e.g., a bruising defect). When the barrier metal layer 163b is electrically connected to an optical black block, an electrostatic defect (e.g., the bruising defect) may be prevented to increase the sensitivity of the image sensor 100.

The barrier metal layer 163b may have a second width CD2 in a horizontal direction (e.g., an X direction) parallel to the upper surface of the rear anti-reflection layer 162. In an embodiment, the second width CD2 of the barrier metal layer 163b may be less than the first widths CD1T and CD1B of the fence 163a.

In an embodiment in which the second width CD2 of the barrier metal layer 163b is less than the first widths CD1T and CD1B of the fence 163a, an undercut portion ucp recessed inward from both side walls of the fence 163a in a lower portion of the fence 163a may be formed in the fence structure 163. The color filter 170 may be buried in the undercut portion ucp to directly contact the barrier metal layer 163b. In an embodiment in which the color filter 170 is buried in the undercut portion ucp, the fence structure 163 may be stably formed on the rear anti-reflection layer 162.

In addition, in an embodiment in which the second width CD2 of the barrier metal layer 163b is less than the first widths CD1T and CD1B of the fence 163a, the light absorption by the barrier metal layer 163b is reduced, thereby further increasing the sensitivity of the image sensor 100. In an embodiment, the second width CD2 may be several tens of nm, for example, the second width CE2 may be in a range of about 20 nm to about 90 nm. The second width CD2 may be referred to as a second threshold size.

The barrier metal layer 163b may have a second height TH2 in a vertical direction (e.g., the Z direction) perpendicular to the upper surface of the rear anti-reflection layer 162. In an embodiment, the second height TH2 of the barrier metal layer 163b may be less than the first height TH1 of the fence 163a. In some embodiments, the second height TH2 of the barrier metal layer 163b may be several nm, for example, the second height TH2 may be in a range of about 2 nm to about 9 nm.

In the image sensor 100, the color filter 170 may be located on both sides of the fence structure 163 and may also be located above the fence structure 163. FIG. 5 illustrates an embodiment in which the color filter 170 is formed above the fence structure 163. However, in embodiments in which the passivation layer 172 is formed above the fence structure 163 and the color filter 170 is not formed above the fence structure 163, the color filters 170 may be separated from each other with the fence structure 163.

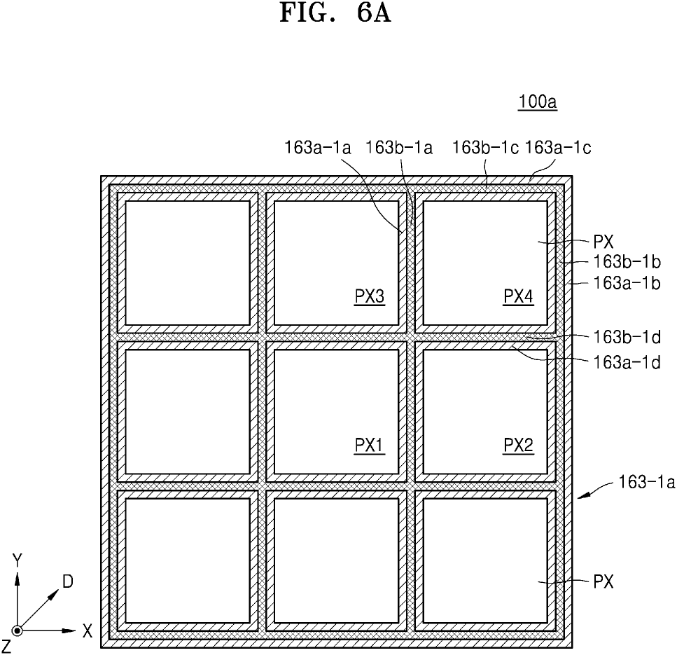

FIGS. 6A and 6B are plan views illustrating fence structures 163-1a and 163-1b of image sensors 100a and 100b according to embodiments of the present inventive concept.

The fence structures 163-1a and 163-1b of the image sensors 100a and 100b may correspond to the fence structure 163 of the image sensors 100 of embodiments of FIGS. 3 to 5. The image sensors 100a and 100b may include a plurality of pixels PX, for example, the first pixel PX1, the second pixel PX2, the third pixel PX3, and the fourth pixel PX4. The plurality of pixels PX may be two-dimensionally arranged and spaced apart from each other. An arrangement of the plurality of pixels PX is described with reference to FIG. 3, and thus a description thereof is omitted herein for economy of description.

The fence structure 163-1a shown in FIG. 6A may include first to fourth connection line fence portions 163a-1a, 163a-1b, 163a-1c, and 163a-1d and barrier metal layers 163b-1a, 163b-1b, 163b-1c, and 163b-1d. The fence structure 163-1b shown in FIG. 6B may include first to fourth connection line fence portions 163a-1a, 163a-1b, 163a-1c, and 163a-1d and barrier metal layers 163b-1a′, 163b-1b′, 163b-1c′, and 163b-1d′.

The first to fourth connection line fence portions 163a-1a, 163a-1b, 163a-1c, and 163a-1d may be connected to each other while generally surrounding the pixel PX, as shown in embodiments of FIGS. 6A and 6B.

For example, the fence structures 163-1a, 163-1b may respectively include the first connection line fence portion 163a-1a and the second connection line fence portion 163a-1b generally extending (e.g., in the Y direction) and disposed on left and right sides of the fourth pixel PX4 (e.g., in the X direction).

In addition, the fence structures 163-1a, 163-1b may respectively include the third connection line fence portion 163a-1c and the fourth connection line fence portion 163-1d generally extending (e.g., in the X direction) and disposed on upper and lower sides of the fourth pixel PX4 (e.g., in the Y direction). The first connection line fence portion 163a-1a, the second connection line fence portion 163a-1b, the third connection line fence portion 163a-1c, and the fourth connection line fence portion 163a-1d may be connected to each other.

As shown in FIG. 6A, the barrier metal layers 163b-1a, 163b-1b, 163b-1c, and 163b-1d may be disposed to surround circumferences of the first pixel PX1, the second pixel PX2, the third pixel PX3, and the fourth pixel PX4. In an embodiment, the barrier metal layers 163b-1a, 163b-1b, 163b-1c, and 163b-1d may be respectively connection type patterns completely surrounding the circumference of the pixel PX within the first to fourth connection line fence portions 163a-1a, 163a-1b, 163a-1c, and 163a-1d planarly. The barrier metal layers 163b-la, 163b-1b, 163b-1c, and 163b-1d may be respectively formed directly on the first to fourth connection line fence portions 163a-1a, 163a-1b, 163a-1c, and 163a-1d.

In an embodiment, the barrier metal layers 163b-1a′, 163b-1b′, 163b-1c′, and 163b-1d′ may be disposed to be spaced apart from each other near the first pixel PX1, the second pixel PX2, the third pixel PX3 and the fourth pixel PX4, respectively, as shown in FIG. 6B. The barrier metal layers 163b-1a′, 163b-1b′, 163b-1c′, and 163b-1d′ may be respectively separation type patterns partially surrounding the circumference of the pixel PX within the first to fourth connection line fence portions 163a-1a, 163a-1b, 163a-1c, and 163a-1d planarly. The barrier metal layers 163b-1a′, 163b-1b′, 163b-1c′, and 163b-1d′ may be respectively formed directly on the first to fourth connection line fence portions 163a-1a, 163a-1b, 163a-1c, and 163a-1d.

As described above, the fence structures 163-1a and 163-1b configured as above may reduce crosstalk by reducing interference of light between the pixels PX, for example, between the first to fourth pixels PX1, PX2, PX3, and PX4, and may increase the sensitivity of the image sensors 100a and 100b by preventing an electrostatic defect (e.g., a bruising defect).

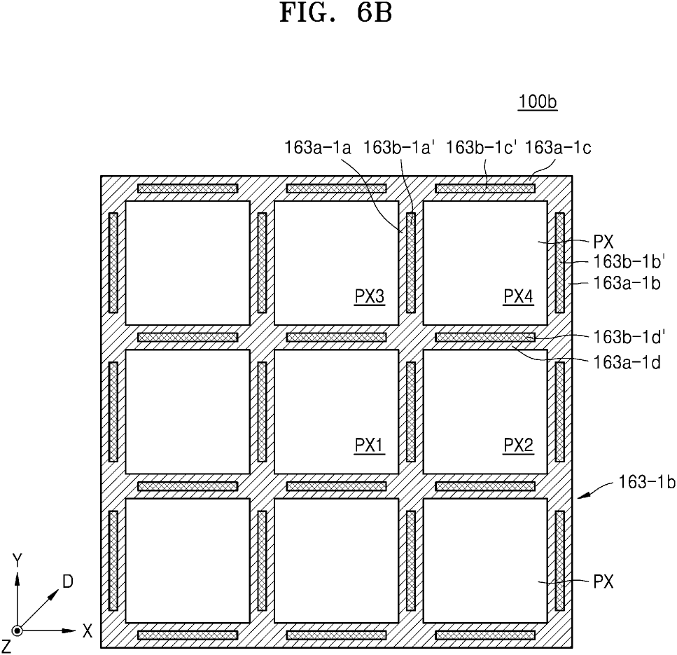

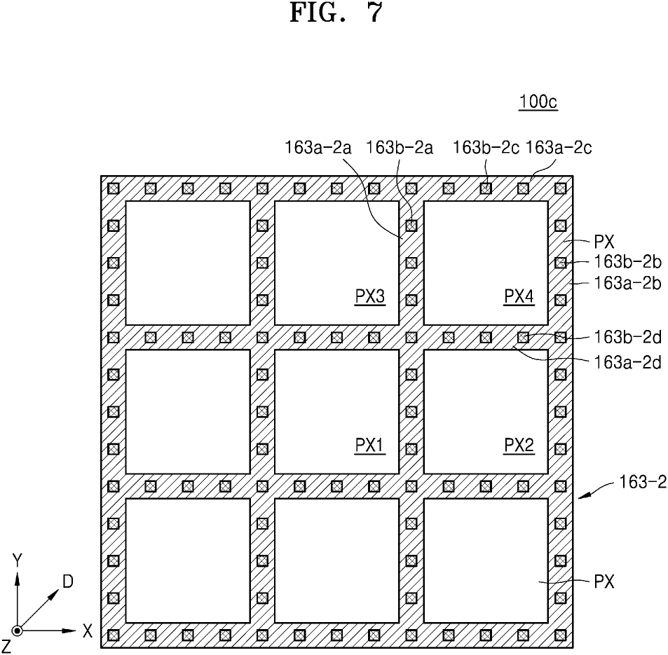

FIG. 7 is a plan view illustrating a fence structure 163-2 of an image sensor 100c according to an embodiment of the present inventive concept.

The image sensor 100c is the same as the image sensors 100a and 100b of FIGS. 6A and 6B except that an arrangement or form of barrier metal layers 163b-2a, 163b-2b, and 163b-2c, and 163b-2d in the fence structure 163-2 are different. In FIG. 7, the same descriptions as those given with reference to FIGS. 6A and 6B will be briefly provided or omitted for economy of description.

The image sensor 100c may include a plurality of pixels PX, for example, the first pixel PX1, the second pixel PX2, the third pixel PX3, and the fourth pixel PX4. The fence structure 163-2 may include first to fourth connection line fence portions 163a-2a, 163a-2b, 163a-2c, and 163a-2d and the barrier metal layers 163b-2a, 163b-2b, 163b-2c, and 163b-2d.

The first to fourth connection line fence portions 163a-2a, 163a-2b, 163a-2c, and 163a-2d may be connected to each other while generally surrounding the pixel PX, as shown in FIG. 7.

The barrier metal layers 163b-2a, 163b-2b, 163b-2c, and 163b-2d may be disposed to be spaced apart from each other near the first pixel PX1, the second pixel PX2, the third pixel PX3 and the fourth pixel PX4, respectively. The barrier metal layers 163b-2a, 163b-2b, 163b-2c, and 163b-2d may be respectively formed in the first connection line fence portion 163a-2a, the second connection line fence portion 163a-2b, the third connection line fence portion 163a-2c, and the fourth connection line fence portion 163a-2d.

The barrier metal layers 163b-2a, 163b-2b, 163b-2c, and 163b-2d may surround the pixel PX in a dot form. For example, the barrier metal layers 163b-2a, 163b-2b, 163b-2c, and 163b-2d may be a plurality of dots (dot patterns) spaced apart from each other.

As described above, the fence structure 163-2 configured as above may reduce crosstalk by reducing interference of light between the pixels PX, for example, between the first to fourth pixels PX1, PX2, PX3, and PX4, and may increase sensitivity of the image sensor 100c by preventing an electrostatic defect (e.g., a bruising defect).

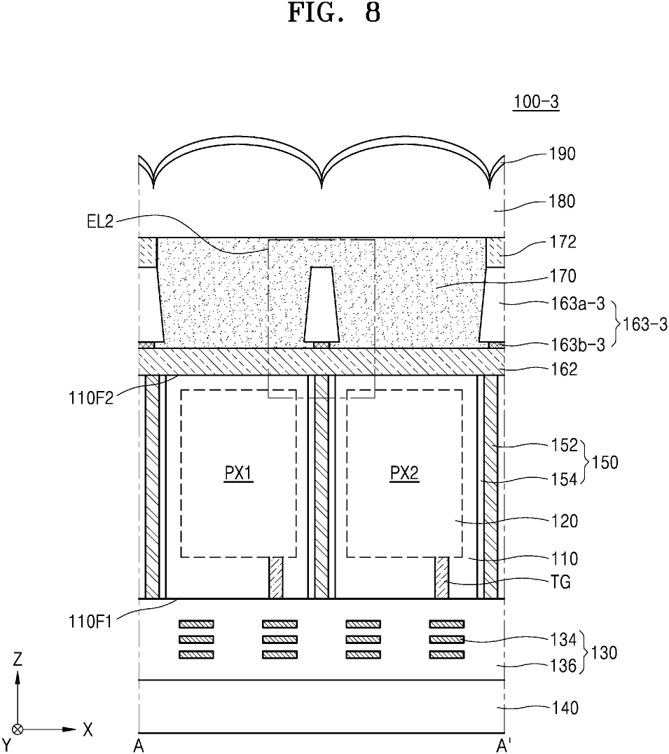

FIG. 8 is a cross-sectional view of an image sensor 100-3 according to an embodiment of the present inventive concept.

The image sensor 100-3 may be the same as the image sensor 100 of FIG. 4 except that a fence 163a-3 constituting the fence structure 163-3 is an air fence. In FIG. 8, the same description as that given with reference to FIG. 4 will be briefly provided or omitted for economy of description.

The image sensor 100-3 may include the substrate 110, the photoelectric conversion region 120, the transfer gate TG, the pixel separation structure 150, the front structure 130, the support substrate 140, the rear anti-reflection layer 162, the fence structure 163-3, the passivation layer 172, the color filter 170, the microlens 180, and the capping layer 190. The image sensor 100-3 is the same as the image sensor 100 of FIG. 4 except for the fence structure 163-3, and thus only the fence structure 163-3 will be described herein.

The fence structure 163-3 may include the fence 163a-3 and a barrier metal layer 163b-3 located below the fence 163a-3. The fence 163a-3 may be an air fence that includes air in an inside portion. The fence structure 163-3 may be disposed on the rear anti-reflection layer 162. The fence structure 163-3 may be referred to as a grid. The fence structure 163-3 may overlap the pixel separation structure 150 in the plan view of FIG. 8.

In an embodiment in which the fence 163a-3 includes air, light incident toward the fence 163a-3 may be totally reflected and directed toward the center of the pixel PX1 or PX2. The fence 163a-3 may prevent light having an inclination angle incident into the color filter 170 disposed on one pixel PX1 or PX2 from entering into the color filter 170 disposed on the adjacent pixel PX1 or PX2. Accordingly, the fence 163a-3 may prevent crosstalk between the plurality of pixels PX1 and PX2.

The barrier metal layer 163b-3 may include a metal material, for example, TiN. The barrier metal layer 163b-3 may be located at a lower portion of the fence structure 163-3 and may be disposed below the fence 163a-3. In an embodiment in which the barrier metal layer 163b-3 is electrically connected to an optical black block, the image sensor 100-3 may reduce an electrostatic defect, for example, a bruising defect. The height (e.g., length in the Z direction) of the barrier metal layer 163b-3 may be lower than the height (e.g., length in the Z direction) of the fence 163a-3.

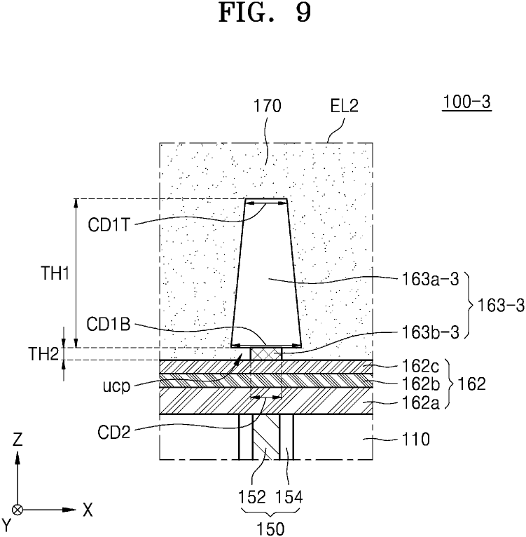

FIG. 9 is an enlarged view of a region EL2 of FIG. 8.

The image sensor 100-3 may be the same as the image sensor 100 of FIG. 5 except that the fence 163a-3 constituting the fence structure 163-3 is an air fence. In FIG. 9, the same description as that given with reference to FIG. 8 will be briefly provided or omitted for economy of description.

The fence structure 163-3 may be located on the rear anti-reflection layer 162 to correspond to or be aligned with the pixel separation structure 150 in a direction perpendicular to the substrate 110 (e.g., the Z direction). The fence structure 163-3 may include the fence 163a-3 and the barrier metal layer 163b-3 located below the fence 163a-3 as described above.

The fence 163a-3 is provided to reduce crosstalk between the pixels (PX1 and PX2 in FIG. 4), as described above. In some embodiments, the fence 163a-3 may include air as described above.

The fence 163a-3 may have the first widths CD1T and CD1B in a horizontal direction (e.g., X direction) that is parallel to the upper surface of the rear anti-reflection layer 162. The fence 163a-3 may have the first height TH1 in a vertical direction (e.g., the Z direction) perpendicular to the upper surface of the rear anti-reflection layer 162. The first widths CD1T and CD1B and the first height TH1 are described with reference to FIG. 5 above, and thus descriptions thereof will be omitted herein for economy of description.

The barrier metal layer 163b-3 is provided to increase sensitivity by preventing an electrostatic defect (e.g., a bruising defect). In an embodiment in which the barrier metal layer 163b-3 is electrically connected to an optical black block, the barrier metal layer 163b-3 may increase the sensitivity of the image sensor 100-3 by preventing the electrostatic defect (e.g., the bruising defect).

The barrier metal layer 163b-3 may have the second width CD2 in a horizontal direction (e.g., the X direction) that is parallel to the upper surface of the rear anti-reflection layer 162. The second width CD2 of the barrier metal layer 163b-3 may be less than the first widths CD1T and CD1B of the fence 163a-3. The second width CD2 is described with reference to FIG. 5 above, and thus a description thereof will be omitted herein for economy of description.

In an embodiment in which the second width CD2 of the barrier metal layer 163b-3 is less than the first widths CD1T and CD1B of the fence 163a-3, the undercut portion ucp recessed inward from both side walls of the fence 163a-3 in a lower portion of the fence 163a may be formed in the fence structure 163-3. The color filter 170 may be buried in the undercut portion ucp. When the color filter 170 is buried in the undercut portion ucp, the fence structure 163-3 may be stably formed on the rear anti-reflection layer 162.

In addition, when the second width CD2 of the barrier metal layer 163b-3 is less than the first widths CD1T and CD1B of the fence 163a-3, the light absorption by the barrier metal layer 163b-3 is reduced, thereby further increasing the sensitivity of the image sensor 100-3.

The barrier metal layer 163b-3 may have the second height TH2 in a vertical direction (e.g., the Z direction) perpendicular to the upper surface of the rear anti-reflection layer 162. The second height TH2 of the barrier metal layer 163b-3 may be less than the first height TH1 of the fence 163a-3. The second height TH2 is described with reference to FIG. 5 above, and thus a description thereof will be omitted herein for economy of description.

FIG. 10 is a plan view illustrating a fence structure 163-3 of an image sensor 100-3a according to an embodiment of the present inventive concept.

The fence structure 163-3 of the image sensor 100-3a may correspond to the fence structure 163-3 of the image sensor 100-3 of embodiments of FIGS. 8 and 9. The image sensor 100-3a may include a plurality of pixels PX, for example, the first pixel PX1, the second pixel PX2, the third pixel PX3, and the fourth pixel PX4. The plurality of pixels PX may be two-dimensionally arranged and spaced apart from each other.

The fence structure 163-3 may include first to fourth connection line fence portions 163a-3a, 163a-3b, 163a-3c, and 163a-3d and barrier metal layers 163b-3a, 163b-3b, 163b-3c, and 163b-3d. As shown in an embodiment of FIG. 10, the first to fourth connection line fence portions 163a-3a, 163a-3b, 163a-3c, and 163a-3d are connected to each other while generally surrounding the pixel PX. In an embodiment, the first to fourth connection line fence portions 163a-3a, 163a-3b, 163a-3c, and 163a-3d may be air fences.

For example, the first and second connection line fence portions 163a-3a and 163a-3b may generally extend (e.g., in the Y direction) and may be disposed on left and right sides of the fourth pixel PX4 (e.g., in the X direction).

In addition, the third connection line fence portion 163a-3c and the fourth connection line fence portion 163-3d may generally extend (e.g., in the X direction) and are disposed on upper and lower sides of the fourth pixel PX4 (e.g., in the Y direction). The first connection line fence portion 163a-3a, the second connection line fence portion 163a-3b, the third connection line fence portion 163a-3c, and the fourth connection line fence portion 163a-3d may be connected to each other. The first to fourth connection line fence portions 163a-3a, 163a-3b, 163a-3c, and 163a-3d may be air fence portions.

The barrier metal layers 163b-3a, 163b-3b, 163b-3c, and 163b-3d may be disposed to be spaced apart from each other near the first pixel PX1, the second pixel PX2, the third pixel PX3 and the fourth pixel PX4, respectively. The barrier metal layers 163b-3a, 163b-3b, 163b-3c, and 163b-3d may be respectively separation type patterns partially surrounding the circumference of the pixel PX within the first to fourth connection line fence portions 163a-3a, 163a-3b, 163a-3c, and 163a-3d planarly. The barrier metal layers 163b-3a, 163b-3b, 163b-3c, and 163b-3d may be respectively formed on the first to fourth connection line fence portions 163a-3a, 163a-3b, 163a-3c, and 163a-3d.

As described above, the fence structure 163-3 configured as above may reduce crosstalk by reducing interference of light between the pixels PX, for example, between the first to fourth pixels PX1, PX2, PX3, and PX4, and may increase the sensitivity of the image sensor 100-3a by preventing an electrostatic defect (e.g., a bruising defect).

FIG. 11 is a plan view illustrating a fence structure 163-4 of an image sensor 100-3b according to an embodiment of the present inventive concept.

The image sensor 100-3b is the same as the image sensor 100-3a of FIG. 10 except that an arrangement or form of barrier metal layers 163b-4a, 163b-4b, 163b-4c, and 163b-4d in the fence structure 163-4 is different. In FIG. 11, the same description as that given with reference to FIG. 10 will be briefly provided or omitted for economy of description.

The image sensor 100-3b may include a plurality of pixels PX, for example, the first pixel PX1, the second pixel PX2, the third pixel PX3, and the fourth pixel PX4. The fence structure 163-4 may include first to fourth connection line fence portions 163a-4a, 163a-4b, 163a-4c, and 163a-4d and barrier metal layers 163b-4a, 163b-4b, 163b-4c, and 163b-4d.

As shown in FIG. 11, the first to fourth connection line fence portions 163a-4a, 163a-4b, 163a-4c, and 163a-4d may be connected to each other while generally surrounding the pixel PX, as shown in FIG. 11. The first to fourth connection line fence portions 163a-4a, 163a-4b, 163a-4c, and 163a-4d may be air fences.

The barrier metal layers 163b-4a, 163b-4b, 163b-4c, and 163b-4d may be disposed to be spaced apart from each other near the first pixel PX1, the second pixel PX2, the third pixel PX3 and the fourth pixel PX4, respectively. The barrier metal layers 163b-4a, 163b-4b, 163b-4c, and 163b-4d may be respectively formed in the first connection line fence portion 163a-4a, the second connection line fence portion 163a-4b, the third connection line fence portion 163a-4c, and the fourth connection line fence portion 163a-4d.

The barrier metal layers 163b-4a, 163b-4b, 163b-4c, and 163b-4d may surround the pixel PX in a dot form. For example, the barrier metal layers 163b-4a, 163b-4b, 163b-4c, and 163b-4d may be a plurality of dots (dot patterns) spaced apart from each other.

As described above, the fence structure 163-4 configured as above may reduce crosstalk by reducing interference of light between the pixels PX, for example, between the first to fourth pixels PX1, PX2, PX3, and PX4, and may increase the sensitivity of the image sensor 100-3b by preventing an electrostatic defect (e.g., a bruising defect).

FIG. 12 is a cross-sectional view of an image sensor 100-5 according to an embodiment of the present inventive concept.

The image sensor 100-5 may be the same as the image sensor 100 of FIG. 4, except that a fence structure 163-5 is different. In FIG. 12, the same description as that given with reference to FIG. 7 will be briefly provided or omitted.

The image sensor 100-5 may include the substrate 110, the photoelectric conversion region 120, the transfer gate TG, the pixel separation structure 150, the front structure 130, the support substrate 140, the rear anti-reflection layer 162, the fence structure 163-5, the passivation layer 172, the color filter 170, the microlens 180, and the capping layer 190. The image sensor 100-5 is the same as the image sensor 100 of FIG. 4 except for the fence structure 163-5, and thus only the fence structure 163-5 will be described herein for economy of description.

The fence structure 163-5 may include a fence 163a-5 and a barrier metal layer 163b-5 buried in the fence 163a-5. The fence 163a-5 may be an insulator fence. The fence structure 163-5 may be disposed on the rear anti-reflection layer 162. The fence structure 163-5 may be referred to as a grid. The fence structure 163-5 may overlap the pixel separation structure 150 in the plan view of FIG. 12.

The fence 163a-5 may prevent crosstalk between the plurality of pixels PX1 and PX2. The barrier metal layer 163b-5 may include a metal material, for example, TiN. The barrier metal layer 163b-5 may be buried at a lower portion of the fence structure 163-5 and may be disposed below the fence 163a-5. In an embodiment in which the barrier metal layer 163b-5 is electrically connected to an optical black block, the image sensor 100-5 may reduce an electrostatic defect, for example, a bruising defect. The height of the barrier metal layer 163b-5 may be lower than the height of the fence 163a-5.

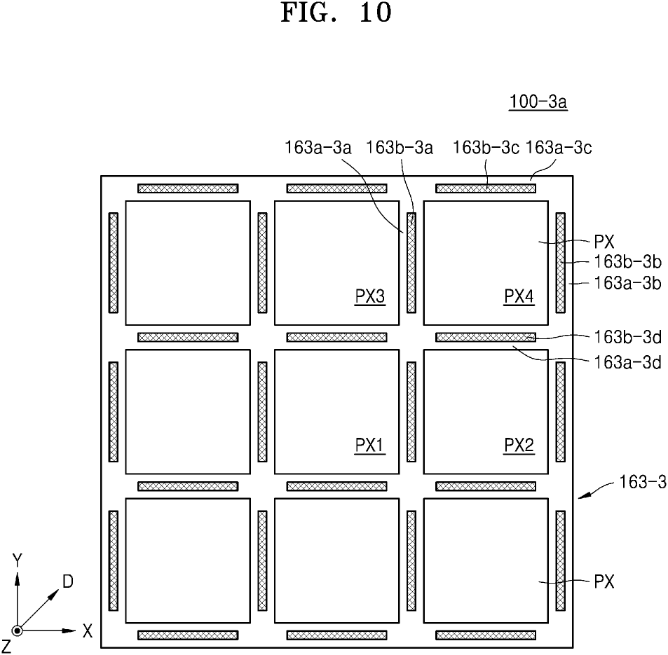

FIG. 13 is an enlarged view of a region EL3 of FIG. 12.

The image sensor 100-5 may be the same as the image sensor 100 of FIG. 5, except that the fence structure 163-5 is different. In FIG. 13, the same description as that given with reference to FIG. 12 will be briefly provided or omitted for economy of description.

The fence structure 163-5 may be located on the rear anti-reflection layer 162 to correspond to or be aligned with the pixel separation structure 150 in a direction perpendicular to the substrate 110 (e.g., in the Z direction). As described above, the fence structure 163-5 may include the fence 163a-5 and the barrier metal layer 163b-5 buried in the fence 163a-5.

The fences 163a-5 may be provided to reduce crosstalk between the pixels (PX1 and PX2 of FIG. 4) as described above. The fences 163a-5 may be disposed in direct contact with the rear anti-reflection layer 162. The fences 163a-5 may have the first widths CD1T and CD1B in a horizontal direction (e.g., the X direction) that is parallel to an upper surface of the rear anti-reflection layer 162.

The fence 163a-5 may have the first height TH1 in a vertical direction (e.g., the Z direction) perpendicular to the upper surface of the rear anti-reflection layer 162. The first widths CD1T and CD1B and the first height TH1 are described with reference to FIG. 5 above, and thus descriptions thereof will be omitted herein for economy of description. The fence 163a-5 may also include a lower portion having the second height TH2. The lower portion of the fence 163a-5 may extend to directly contact an upper surface and sidewalls of the barrier metal layer 163b-5 and an upper surface of the rear anti-reflection layer 162 so that the barrier metal layer 163b-5 is buried in the fence 163a-5. Accordingly, the lower portion of the fence 163a-5 may not form the undercut portion ucp as shown in an embodiment of FIG. 5.

The barrier metal layer 163b-5 may be provided to increase sensitivity by preventing an electrostatic defect (e.g., a bruising defect). In an embodiment in which the barrier metal layer 163b-5 is electrically connected to an optical black block, the barrier metal layer 163b-5 may increase the sensitivity of the image sensor 100-5 by preventing the electrostatic defect (e.g., the bruising defect).

The barrier metal layer 163b-5 may have the second width CD2 in a horizontal direction (e.g., the X direction) that is parallel to the upper surface of the rear anti-reflection layer 162. The second width CD2 of the barrier metal layer 163b-5 may be less than the first widths CD1T and CD1B of the fence 163a-5. The second width CD2 is described with reference to FIG. 5 above, and thus a description thereof will be omitted herein for economy of description.

In an embodiment in which the second width CD2 of the barrier metal layer 163b-5 is less than the first widths CD1T and CD1B of the fence 163a-5, the light absorption by the barrier metal layer 163b-5 is reduced, thereby further increasing the sensitivity of the image sensor 100-5.

The barrier metal layer 163b-5 may have the second height TH2 in a vertical direction (i.e., Z direction) perpendicular to the upper surface of the rear anti-reflection layer 162. The second height TH2 of the barrier metal layer 163b-5 may be less than the first height TH1 of the fence 163a-5. The second height TH2 is described with reference to FIG. 5 above, and thus a description thereof will be omitted herein for economy of description. In the image sensor 100-5, the color filter 170 may be located on both sides of the fence structure 163-5 and may also be located above the fence structure 163-5.

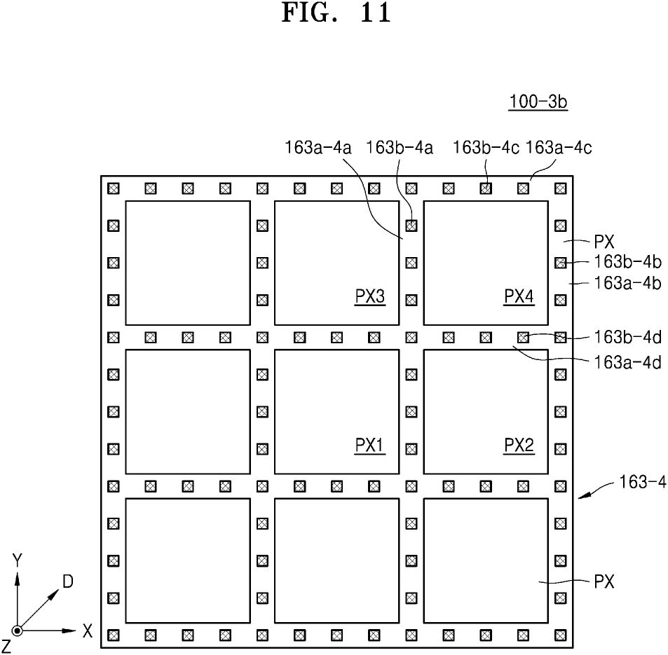

FIG. 14 is a cross-sectional view of an image sensor 100-6 according to an embodiment of the present inventive concept.

The image sensor 100-6 may be the same as the image sensor 100-5 of FIG. 12 except that a fence 163a-6 constituting a fence structure 163-6 is an air fence. In FIG. 14, the same description as that given with reference to FIG. 12 will be briefly provided or omitted for economy of description.

The image sensor 100-6 may include the substrate 110, the photoelectric conversion region 120, the transfer gate TG, the pixel separation structure 150, the front structure 130, the support substrate 140, the rear anti-reflection layer 162, the fence structure 163-6, the passivation layer 172, the color filter 170, the microlens 180, and the capping layer 190. Since the image sensor 100-6 is the same as the image sensor 100-5 of FIG. 12 except for the fence structure 163-6, only the fence structure 163-6 will be described herein for economy of description.

The fence structure 163-6 may include a fence 163a-6 and a barrier metal layer 163b-6 buried in the fence 163a-6. The fence 163a-6 may be an air fence including air inside. The fence structure 163-6 may be disposed on the rear anti-reflection layer 162 The fence structure 163-6 may be referred to as a grid. The fence structure 163-6 may overlap the pixel separation structure 150 in the plan view of FIG. 3.

In an embodiment in which the fence 163a-6 includes air, light incident toward the fence 163a-6 may be totally reflected and directed toward the center of the pixel PX1 or PX2. The fence 163a-6 may prevent light having an inclination angle incident into the color filter 170 disposed on one pixel PX1 or PX2 from entering into the color filter 170 disposed on the adjacent pixel PX1 or PX2. Accordingly, the fence 163a-6 may prevent crosstalk between the plurality of pixels PX1 and PX2.

The barrier metal layer 163b-6 may include a metal material, for example, TiN. The barrier metal layer 163b-6 may be buried in a lower portion of the fence structure 163-6, that is, below the fence 163a-6. In an embodiment in which the barrier metal layer 163b-6 is electrically connected to an optical black block, the image sensor 100-6 may reduce an electrostatic defect, for example, a bruising defect. The height of the barrier metal layer 163b-6 may be lower than the height of the fence 163a-6.

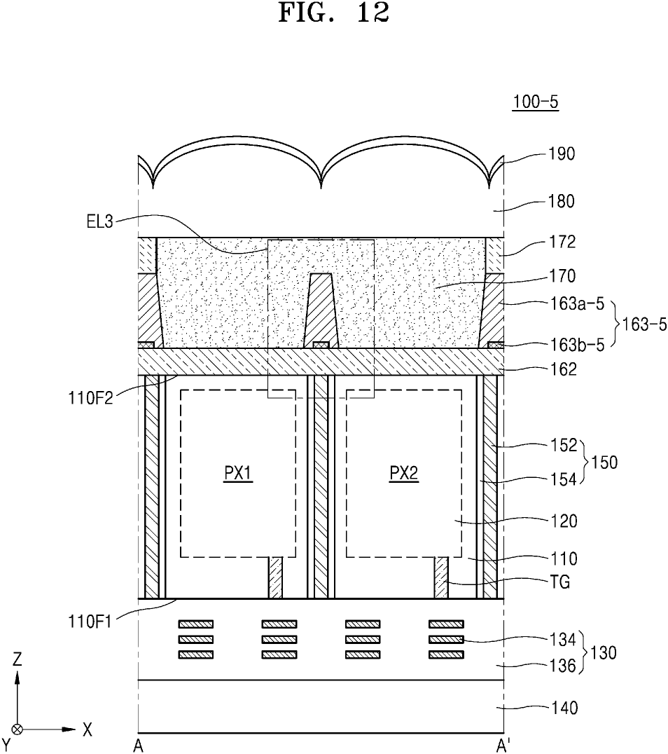

FIG. 15 is an enlarged view of region EL4 of FIG. 14.

The image sensor 100-6 may be the same as the image sensor 100-5 of FIG. 13 except that the fence 163a-6 constituting the fence structure 163-6 is an air fence. In FIG. 15, the same description as that given with reference to FIG. 13 will be briefly provided or omitted for economy of description.

The fence structure 163-6 may be located on the rear anti-reflection layer 162 to correspond to or be aligned with the pixel separation structure 150 in a direction perpendicular to the substrate 110. The fence structure 163-6 may include the fence 163a-6 and the barrier metal layer 163b-6 buried in the fence 163a-6 below the fence 163a-6 as described above.

The fence 163a-6 is provided to suppress crosstalk between the pixels (PX1 and PX2 in FIG. 4), as described above. In some embodiments, the fence 163a-6 may include air as described above.

The fence 163a-6 may have the first widths CD1T and CD1B in a horizontal direction (e.g., the X direction) that is parallel to an upper surface of the rear anti-reflection layer 162. The fence 163a-6 may have the first height TH1 in a vertical direction (e.g., the Z direction) perpendicular to the upper surface of the rear anti-reflection layer 162. The first widths CD1T and CD1B and the first height TH1 are described with reference to FIG. 5 above, and thus descriptions thereof will be omitted herein for economy of description.

The barrier metal layer 163b-6 is provided to increase sensitivity by preventing an electrostatic defect (e.g., a bruising defect). In an embodiment in which the barrier metal layer 163b-6 is electrically connected to an optical black block, the barrier metal layer 163b-6 may increase the sensitivity of the image sensor 100-6 by suppressing the electrostatic defect (e.g, the bruising defect).

The barrier metal layer 163b-6 may have the second width CD2 in a horizontal direction (e.g., the X direction) that is parallel to an upper surface of the rear anti-reflection layer 162. The second width CD2 of the barrier metal layer 163b-6 may be less than the first widths CD1T and CD1B of the fence 163a-6. The second width CD2 is described with reference to FIG. 5 above, and thus a description thereof will be omitted herein for economy of description.

In an embodiment in which the second width CD2 of the barrier metal layer 163b-6 is less than the first widths CD1T and CD1B of the fence 163a-6, the light absorption by the barrier metal layer 163b-6 is reduced, thereby further increasing the sensitivity of the image sensor 100-6.

The barrier metal layer 163b-6 may have the second height TH2 in a vertical direction (e.g., the Z direction) perpendicular to the upper surface of the rear anti-reflection layer 162. The second height TH2 of the barrier metal layer 163b-6 may be less than the first height TH1 of the fence 163a-6. The second height TH2 is described with reference to FIG. 5 above, and thus a description thereof will be omitted herein for economy of description.

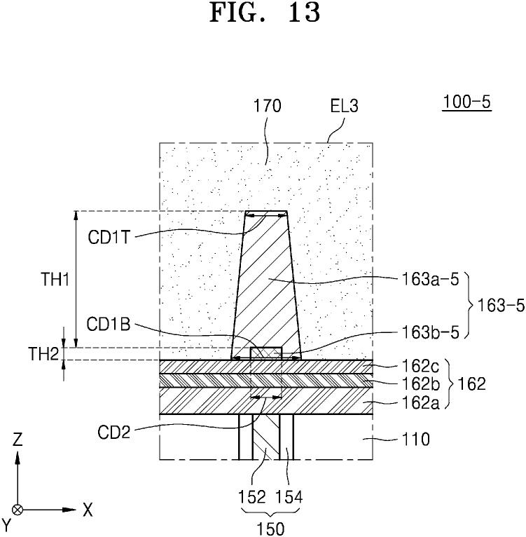

FIG. 16 is a plan view of a pixel PXa of an image sensor 100-7 according to an embodiment of the present inventive concept.

Specifically, the image sensor 100-7 is the same as the image sensor 100 of FIGS. 3 to 5 except that the image sensor 100-7 includes two photoelectric conversion elements PD1 and PD2 in the pixel PXa. In FIG. 16, the same description as those given with reference to FIGS. 3 to 5 will be briefly provided or omitted for economy of description.

The image sensor 100-7 may include the pixel PXa. The pixel PXa may correspond to the pixel PX of FIG. 3. The pixel PXa may include the first photoelectric conversion element PD1 and the second photoelectric conversion element PD2.

A color filter (170 of FIG. 4) may be disposed below the microlens 180, and the first and second photoelectric conversion elements PD1 and PD2 may be disposed below the color filter 170. The first and second photoelectric conversion elements PD1 and PD2 may be formed on a substrate (110 of FIG. 4). In an embodiment shown in FIG. 16, the first photoelectric conversion element PD1 and the second photoelectric conversion element PD2 may be disposed side by side (e.g., in the X direction) below the microlens 180. As described above, the pixel PXa of the image sensor 100-7 may include the two photoelectric conversion elements PD1 and PD2 to be used as a focus pixel.

FIG. 17 is a plan view of a pixel PXb of an image sensor 100-8 according to an embodiment of the present inventive concept.

The image sensor 100-8 is the same as the image sensor 100 of FIGS. 3 to 5, except that the image sensor 100-8 includes four photoelectric conversion elements PD1, PD2, PD4, and PD4 in the pixel PXb. In FIG. 17, the same descriptions as those given with reference to FIGS. 3 to 5 will be briefly provided or omitted for economy of description.

The image sensor 100-8 may include the pixel PXb. The pixel PXb may correspond to the pixel PX of FIG. 3. The pixel PXb may include the first photoelectric conversion element PD1, the second photoelectric conversion element PD2, the third photoelectric conversion element PD3, and the fourth photoelectric conversion element PD4.

A color filter (170 of FIG. 4) may be disposed below the microlens 180, and the first to fourth photoelectric conversion elements PD1, PD2, PD3 and PD4 may be disposed below the color filter 170. The first to fourth photoelectric conversion elements PD1, PD2, PD3, and PD4 may be formed on the substrate 110 of FIG. 4. In an embodiment, the first to fourth photoelectric conversion elements PD1, PD2, PD3, and PD4 may be arranged side by side below the microlens 180. As described above, the pixel PXb of the image sensor 100-8 may include the four photoelectric conversion elements PD1, PD2, PD3, and PD4 to be used as a focus pixel.

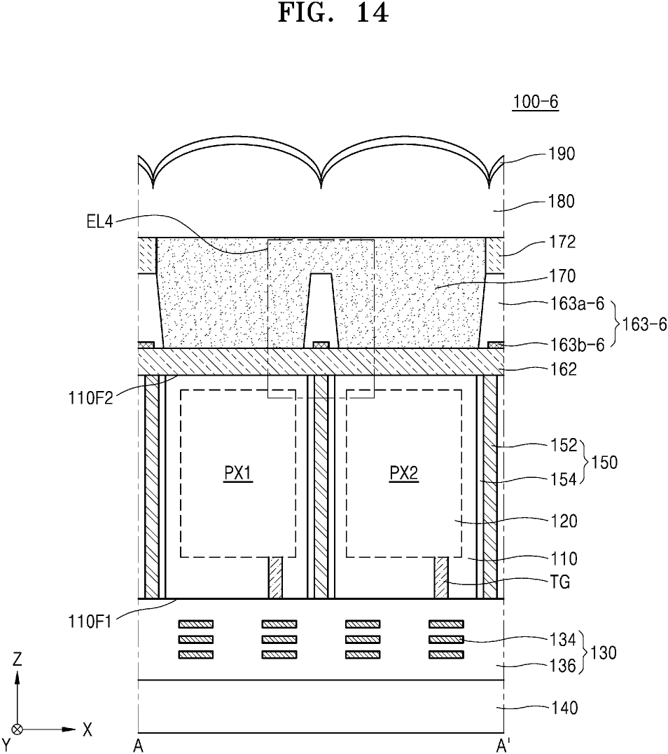

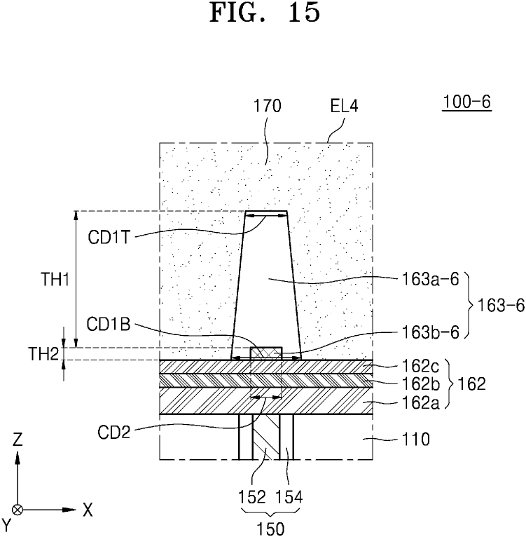

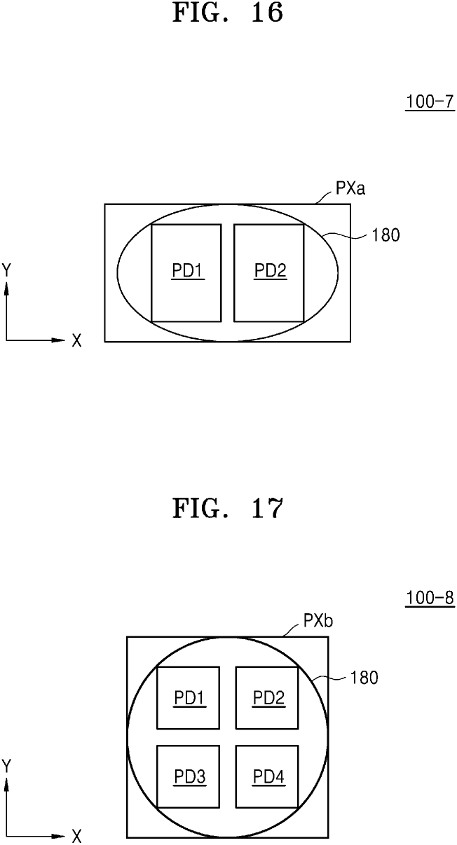

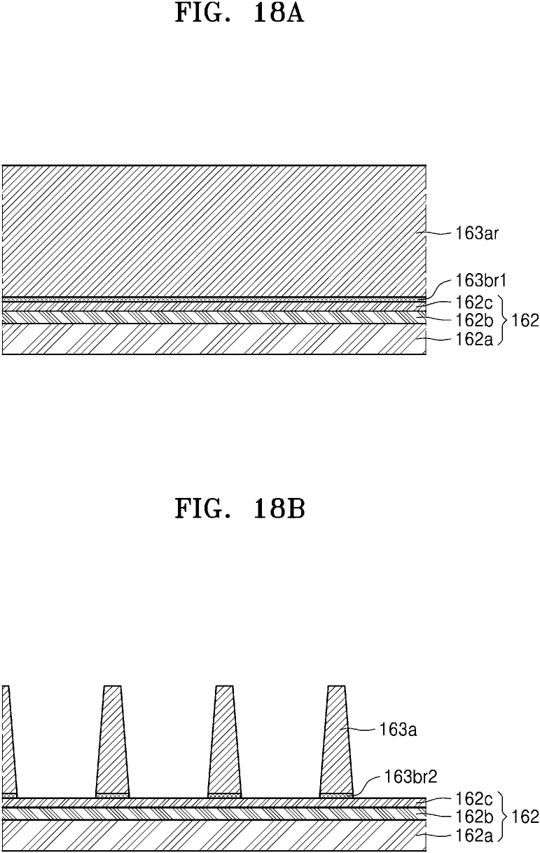

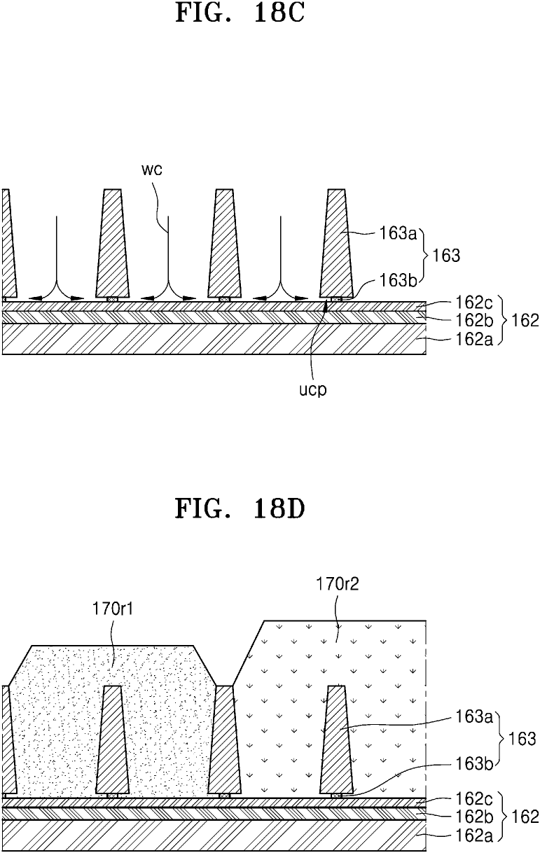

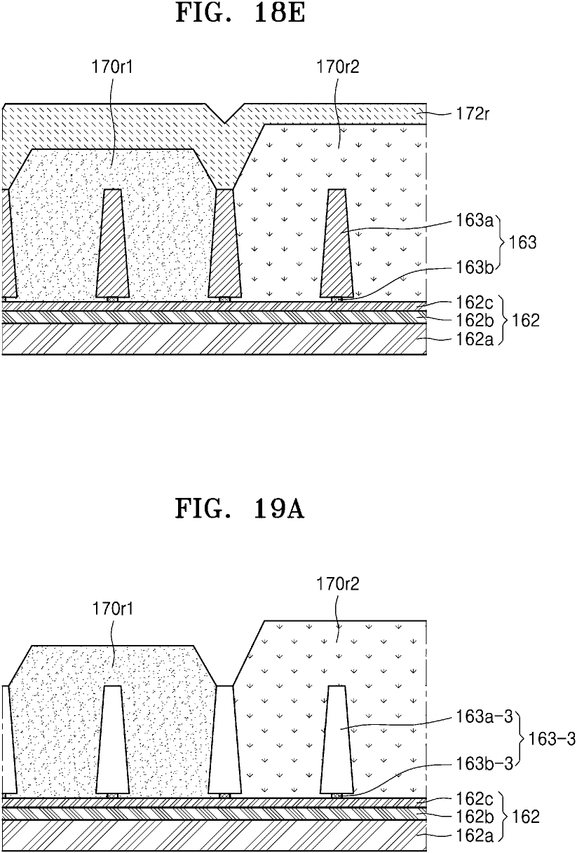

FIGS. 18A to 18E are cross-sectional views illustrating a method of manufacturing the fence structure 163 of the image sensor 100 according to embodiments of the present inventive concept.

FIGS. 18A to 18E are cross-sectional views illustrating the method of manufacturing the fence structure 163 constituting the image sensor 100 of FIGS. 3 to 5. In FIGS. 18A to 18E, the same reference numerals as in FIGS. 3 to 5 denote the same members. In FIGS. 18A to 18E, the same descriptions as those given with reference to FIGS. 3 to 5 will be briefly provided or omitted for economy of description.

Referring to FIG. 18A, a barrier metal material layer 163br1 and a fence material layer 163ar are formed on the rear anti-reflection layer 162. The rear anti-reflection layer 162 may include the plurality of sub rear anti-reflection layers, such as the first to third sub rear anti-reflection layers 162a, 162b, and 162c.

The barrier metal material layer 163br1 may include a metal material, for example, TiN. The fence material layer 163ar may include silicon oxide. The height (e.g., a thickness) of the fence material layer 163ar is greater than the height (e.g., a thickness) of the barrier metal material layer 163br1. In some embodiments, the height of the fence material layer 163ar may be several hundred nm or less, for example, in a range of about 300 nm to about 500 nm, and the height of the barrier metal material layer 163br1 may be several nm, for example, in a range of about 2 nm to about 9 nm.

Referring to FIG. 18B, the fence material layer 163ar and the barrier metal material layer 163br1 are patterned using a photolithography process Accordingly, the fence 163a and a barrier metal material pattern 163br2 are formed. The fence 163a and the barrier metal material pattern 163br2 may respectively include a plurality of fence patterns and a plurality of barrier metal patterns spaced apart from each other. The fence 163a may be an insulator fence.

When the fence material layer 163ar is patterned, an upper width of the fence 163a may be less than a lower width thereof. The barrier metal material pattern 163br2 may be formed on a lower surface of the fence 163a and a surface of the rear anti-reflection layer 162.

Referring to FIG. 18C, a part of the barrier metal material pattern (163br2 of FIG. 18B) formed on a lower portion of the fence 163a is isotropically etched using a wet etching solution. In FIG. 18C, reference numeral wc denotes that the wet etching solution penetrates into the barrier metal material pattern (163br2 of FIG. 18B) on the lower portion of the fence 163a. Accordingly, the undercut portion ucp is formed in the lower portion of the fence 163a and the barrier metal layer 163b is formed. In addition, the fence structure 163 is manufactured by the fence 163a and the barrier metal layer 163b.

The undercut portion ucp may be a portion recessed inward from both side walls of the fence 163a in the lower portion of the fence 163a. The fence 163a may be spaced apart (e.g., in the Z direction) from the upper surface of the rear anti-reflection layer 162 due to the undercut portion ucp.

Referring to FIG. 18D, color filter material layers, such as first and second color filter material layers 170r1 and 170r2, are formed on the rear anti-reflection layer 162 to sufficiently cover the fence structure 163. The first and second color filter material layers 170r1 and 170r2 are formed to a sufficient thickness on the fence structure 163 while filling between the fence structures 163 on the rear anti-reflection layer 162. The fence structure 163 may be buried inside the first and second color filter material layers 170r1, 170r2, or a part of an upper surface thereof may be exposed to the outside.

While an embodiment shown in FIG. 18D shows the color filter material layers including the first color filter material layer 170r1 and the second color material layer 170r2 identified by the fence structure 163 formed in a central portion, the number of color filter material layers is not necessarily limited thereto.

In some embodiments, heights of the first color filter material layer 170r1 and the second color material layer 170r2 may be substantially equal to each other. In some embodiments, each of the color filter material layers 170r1 and 170r2 may be a green filter material layer, a blue filter material layer, or a red filter material layer For example, the color filter material layer 170r1 may be the green filter material layer, and the color filter material layer 170r2 may be the blue filter material layer. However, embodiments of the present inventive concept are not necessarily limited thereto.

Referring to FIG. 18E, a passivation material layer 172r is formed on the first and second color filter material layers 170r1 and 170r2 in which the fence structure 163 is buried. In some embodiments, the passivation material layer 172r may include aluminum oxide.

The passivation material layer 172r and the first and second color filter material layers 170r1 and 170r2 formed through the manufacturing process described above may correspond to the passivation layer 172 and the first and second color filters 170-1 and 170-2 described above, respectively. The color filters may include the first color filter 170-1 and the second color filter 170-2 identified by the passivation layer 172. The first color filter 170-1 may correspond to the color filter 170 of FIGS. 4 and 5. The passivation layer 172 may correspond to the passivation layer 172 of FIG. 4.

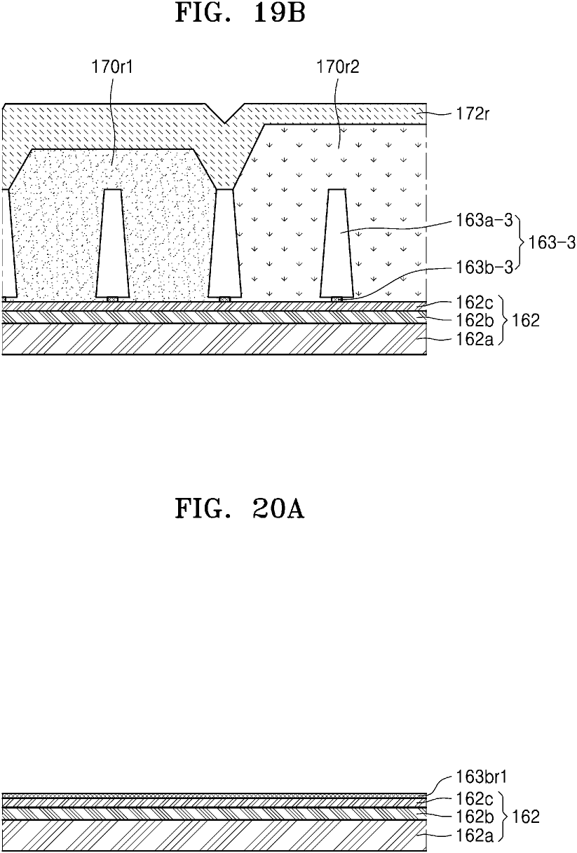

FIGS. 19A and 19B are cross-sectional views illustrating a method of manufacturing the fence structure 163-3 of the image sensor 100-3 according to embodiments of the present inventive concept.

FIGS. 19A and 19B are cross-sectional views illustrating the method of manufacturing the fence structure 163-3 constituting the image sensor 100-3 of FIGS. 8 and 9. In FIGS. 19A and 19B, the same reference numerals as in FIGS. 8 and 9 denote the same members. With respect to FIGS. 19A and 19B, the same descriptions as those given with reference to FIGS. 8 and 9 will be briefly provided or omitted for economy of description.

The manufacturing process of FIGS. 18A to 18D above is performed. In this embodiment, the fence structure 163 and the color filter material layers sufficiently covering the fence structure 163 may be formed on the rear anti-reflection layer 162. The fence structure 163 may include the fence 163a configured as an insulator and the barrier metal layer 163b. The color filter material layers may include the first color filter material layer 170r1 and the second color filter material layer 170r2 identified by the fence structure 163 formed in a central portion.

Referring to FIG. 19A, the fence 163a buried in the first and second color filter material layers 170rl and 170r2 is removed with a wet etching solution. For example, the insulator constituting the fence 163a, for example, silicon oxide, is removed with the wet etching solution. Accordingly, the fence 163a may be formed as the fence 163a-3 including air. The fence 163a-3 may be an air fence.

A barrier metal layer 163b-3 may be formed on a lower portion of the fence 163a-3. The barrier metal layer 163b-3 may correspond to the barrier metal layer 163b of FIG. 18D. The fence 163a-3 and the barrier metal layer 163b-3 may be the fence structure 163-3. The fence structure 163-3 may be formed in the first and second color filter material layers 170r1 and 170r2.

Referring to FIG. 19B, as shown in FIG. 19B, the passivation material layer 172r is formed on the first and second color filter material layers 170rl and 170r2 in which the fence structure 163-3 is buried. In some embodiments, the passivation material layer 172r may include aluminum oxide.

The passivation material layer 172r and the first and second color filter material layers 170r1 and 170r2 formed through the manufacturing process described above may correspond to the passivation layer 172 and color filters 170-1 and 170-2 described above, respectively. The color filters 170-1 and 170-2 may include the first color filter 170-1 and the second color filter 170-2 identified by the passivation layer 172. The color filter 170-1 may correspond to the color filter 170 of FIGS. 8 and 9. The passivation layer 172 may correspond to the passivation layer 172 of FIG. 8.

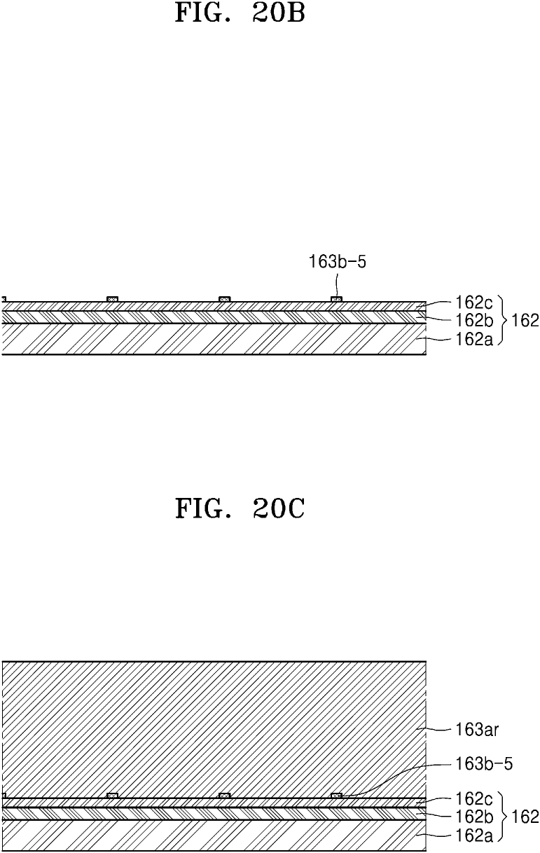

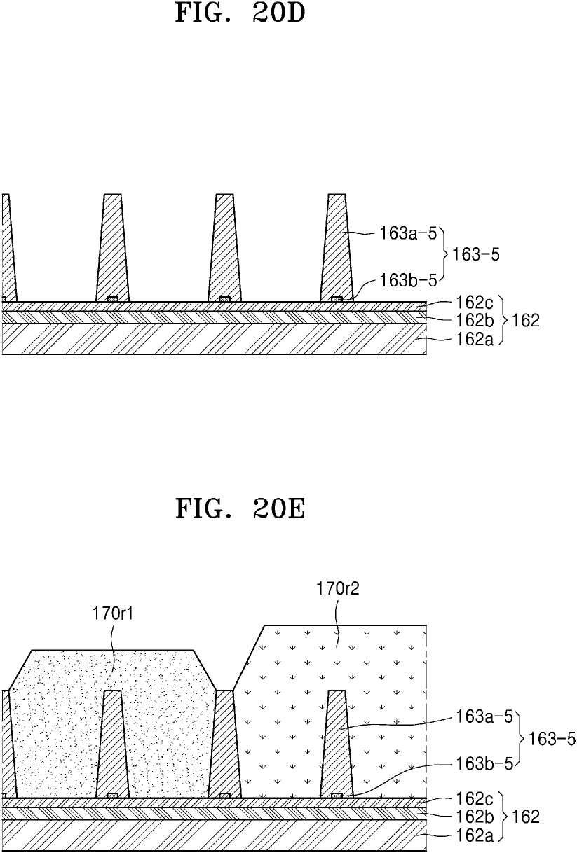

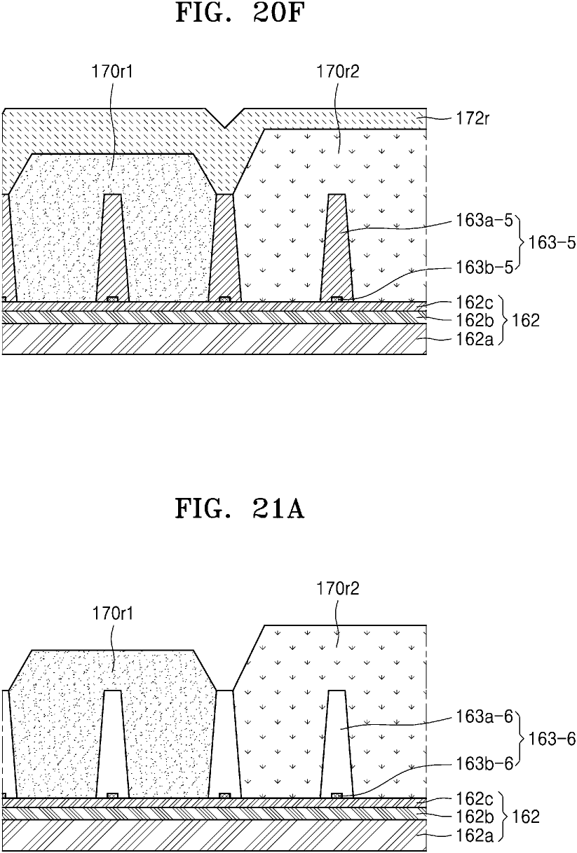

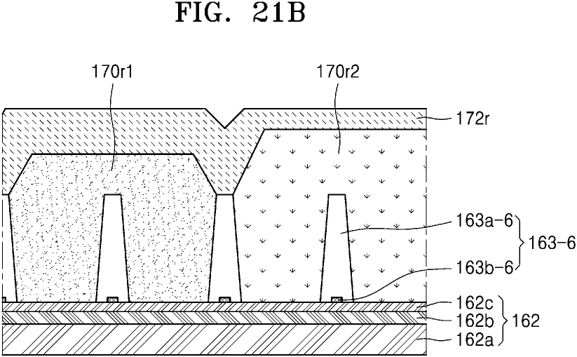

FIGS. 20A to 20F are cross-sectional views illustrating a method of manufacturing the fence structure 163-5 of the image sensor 100-5 according to embodiments of the present inventive concept.

FIGS. 20A to 20F are cross-sectional views illustrating the method of manufacturing the fence structure 163-5 constituting the image sensor 100-5 of FIGS. 12 and 13. In FIGS. 20A to 20F, the same reference numerals as in FIGS. 12 and 13 denote the same members. In FIGS. 20A to 20F, the same descriptions as those given with reference to FIGS. 12 and 13 will be briefly provided or omitted for economy of description.

Referring to FIG. 20A, the barrier metal material layer 163br1 is formed on the rear anti-reflection layer 162. The rear anti-reflection layer 162 may include the plurality of sub rear anti-reflection layers, such as the first to third sub rear anti-reflection layers 162a, 162b, and 162c. The barrier metal material layer 163br1 may include a metal material, for example, TiN. The height (e.g., thickness) of the barrier metal material layer 163br1 may be several nm, for example, in a range of about 2 nm to about 9 nm.

Referring to FIG. 20B, the barrier metal layer 163br1 is patterned to form the barrier metal layer 163b-5. The barrier metal layer 163b-5 may include a plurality of barrier metal patterns spaced apart from each other.

Referring to FIG. 20C, the fence material layer 163ar is formed on the barrier metal layer 163b-5 and the rear anti-reflection layer 162. The fence material layer 163ar may include silicon oxide. The height (e.g., thickness) of the fence material layer 163ar is greater than the height (e.g., thickness) of the barrier metal layer 163b-5. In some embodiments, the height of the fence material layer 163ar may be less than or equal to several hundred nm, for example, in a range of about 300 nm to about 500 nm.

Referring to FIG. 20D, the fence material layer 163ar is patterned using a photolithography process to form the fence 163a-5 and the barrier metal layer 163b-5 buried in the fence 163a-5. The fence 163a-5 and the barrier metal layer 163b-5 may respectively include a plurality of fence patterns and a plurality of barrier metal patterns spaced apart from each other.

The fences 163a-5 may be an insulator fence. When the fence material layer (163ar of FIG. 20C) is patterned, an upper width of the fence 163a-5 may be less than a lower width thereof. A width of the barrier metal layer 163b-5 may be less than a width of the fence 163a-5, for example, the lower width. The fence 163a-5 and the barrier metal layer 163b-5 constitute the fence structure 163-5.

Referring to FIG. 20E, the color filter material layers are formed on the rear anti-reflection layer 162 to sufficiently cover the fence structure 163-5. The color filter material layers, such as the first and second color material layers 170r1 and 170r2, are formed to a sufficient thickness on the fence structure 163-5 while filling between the fence structures 163-5 on the rear anti-reflection layer 162.

The fence structure 163-5 may be buried in the first and second color filter material layers 170r1 and 170r2, or a part of an upper surface thereof may be exposed to the outside. The color filter material layers may include the first color filter material layer 170r1 and the second color material layer 170r2 identified by the fence structure 163-5 formed in a central portion.

In some embodiments, heights of the first color filter material layer 170r1 and the second color material layer 170r2 may be substantially equal to each other. In some embodiments, each of the color filter material layers 170r1 and 170r2 may be a green filter material layer, a blue filter material layer, or a red filter material layer . For example, the color filter material layer 170r1 may be the green filter material layer, and the color filter material layer 170r2 may be the blue filter material layer. However, embodiments of the present inventive concept are not necessarily limited thereto.

Referring to FIG. 20F, the passivation material layer 172r is formed on the first and second color filter material layers 170r1 and 170r2 in which the fence structure 163-5 is buried. In some embodiments, the passivation material layer 172r may include aluminum oxide.

The passivation material layer 172r and the first and second color filter material layers 170r1 and 170r2 formed through the manufacturing process described above may correspond to the passivation layer 172 and the first and second color filters 170-1 and 170-2 described above, respectively. The color filters may include the first color filter 170-1 and the second color filter 170-2 identified by the passivation layer 172. The color filter 170-1 may correspond to the color filter 170 of FIGS. 12 and 13. The passivation layer 172 may correspond to the passivation layer 172 of FIG. 12.

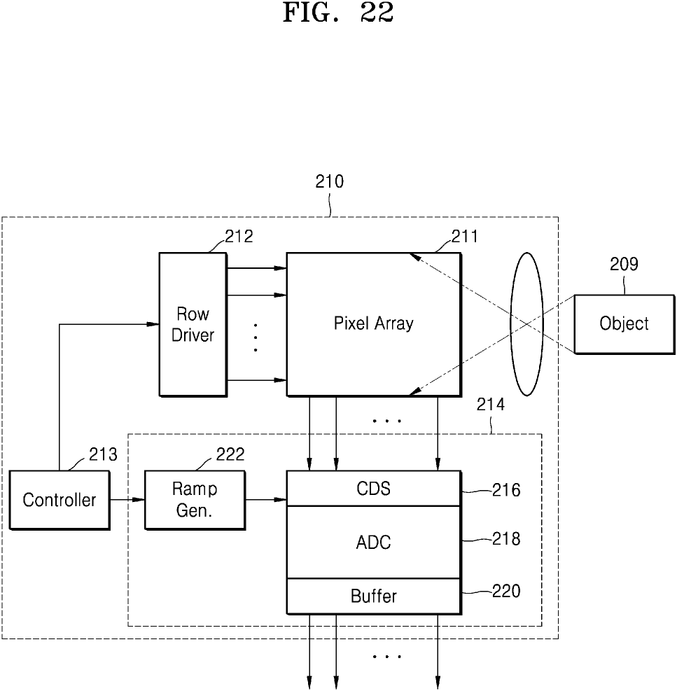

FIGS. 21A and 21B are cross-sectional views illustrating a method of manufacturing the fence structure 163-6 of the image sensor 100-6 according to embodiments of the present inventive concept.

FIGS. 21A and 21B are cross-sectional views illustrating the method of manufacturing the fence structure 163-6 constituting the image sensor 100-6 of FIGS. 14 and 15. In FIGS. 21A and 21B, the same reference numerals as in FIGS. 14 and 15 denote the same members. In FIGS. 21A and 21B, the same descriptions as those given with reference to FIGS. 14 and 15 will be briefly provided or omitted.

The manufacturing process of FIGS. 20A to 20E above is performed . In an embodiment, the fence structure 163-5 and the first and second color filter material layers 170r1 and 170r2 sufficiently covering the fence structure 163-5 may be formed on the rear anti-reflection layer 162. The fence structure 163-5 may include the fence 163a-5 made of an insulator and the barrier metal layer 163b-5. The color filter material layers may include the first color filter material layer 170r1 and the second color filter material layer 170r2 identified by the fence structure 163-5 formed in a central portion.

Referring to FIG. 21A, the fence 163a-5 buried in the first and second color filter material layers 170r1 and 170r2 are removed with a wet etching solution. For example, an insulator constituting the fence 163a-5, for example, silicon oxide, is removed with the wet etching solution. Accordingly, the fence 163a-5 may be the fence 163a-6 including air. The fence 163a-6 may be an air fence.

The barrier metal layer 163b-6 may be formed on a lower portion of the fence 163a-6. The barrier metal layer 163b-6 may correspond to the barrier metal layer 163b-5 of FIG. 20E. The fence 163a-6 and the barrier metal layer 163b-6 may be the fence structure 163-6. The fence structure 163-6 may be formed in the first and second color filter material layers 170r1 and 170r2.

Referring to FIG. 21B, the passivation material layer 172r is formed on the first and second color filter material layers 170r1 and 170r2 in which the fence structure 163-6 is buried. In some embodiments, the passivation material layer 172r may include aluminum oxide.

The passivation material layer 172r and the first and second color filter material layers 170r1 and 170r2 formed through the manufacturing process described above may correspond to the passivation layer 172 and the color filters 170-1 and 170-2 described above, respectively. The color filters may include the first color filter 170-1 and the second color filter 170-2 identified by the passivation layer 172. The color filter 170-1 may correspond to the color filter 170 of FIGS. 14 and 15. The passivation layer 172 may correspond to the passivation layer 172 of FIG. 14.

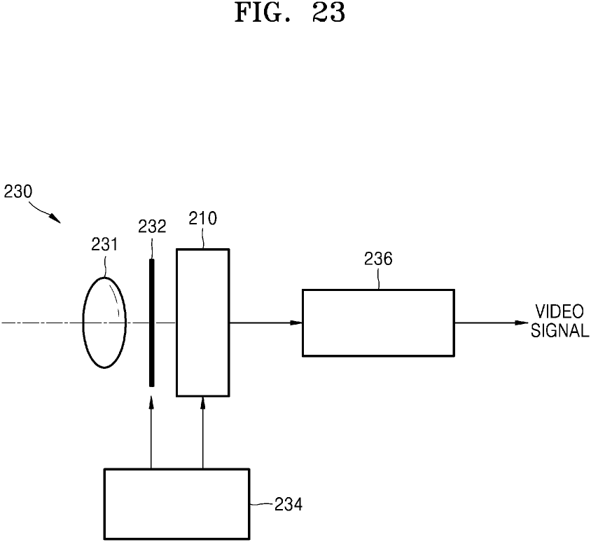

FIG. 22 is a block diagram illustrating a configuration of an image sensor 210 according to an embodiment of the present inventive concept.

The image sensor 210 may include a pixel array 211, a controller 213, a row driver 212, and a pixel signal processor 214. The image sensor 210 may include at least one of the image sensors 100, 100a, 100b, 100c, 100-3, 100-3a, 100-3b, 100-5, 100-6, 100-7, or 100-8 described above.

The pixel array 211 may include a plurality of two-dimensionally arranged unit pixels, and each unit pixel may include a photoelectric conversion element. The photoelectric conversion element may absorb light to generate electric charges, and an electric signal (e.g., an output voltage) according to the generated electric charges may be provided to the pixel signal processor 214 through a vertical signal line. The unit pixels included in the pixel array 211 may provide one output voltage at a time in a row unit.

Accordingly, unit pixels belonging to one row of the pixel array 211 may be simultaneously activated by a selection signal output by the row driver 212. The unit pixels belonging to the selected row may provide an output voltage according to the absorbed light to an output line of a corresponding column.

The controller 213 may control the row driver 212 to allow the pixel array 211 to absorb light and accumulate electric charges or temporarily store the accumulated electric charges, and output an electrical signal according to the stored electric charges to the outside of the pixel array 211. Also, the controller 213 may control the pixel signal processor 214 to measure the output voltage provided by the pixel array 211.

In an embodiment, the pixel signal processor 214 may include a correlated double sampler (CDS) 216, an analog-to-digital converter (ADC) 218, and a buffer 220. The CDS 216 may sample and hold the output voltage provided by the pixel array 211. The CDS 216 may double-sample a specific noise level and a level according to the generated output voltage, and output a level corresponding to a difference between the levels. Also, the CDS 216 may receive ramp signals generated by a ramp signal generator 222, compare the ramp signals with each other, and output a comparison result. The ADC 218 may convert an analog signal corresponding to the level received from the CDS 216 into a digital signal. The buffer 220 may latch the digital signal, and latched signals may be sequentially output to the outside of the image sensor 210 and transferred to an image processor

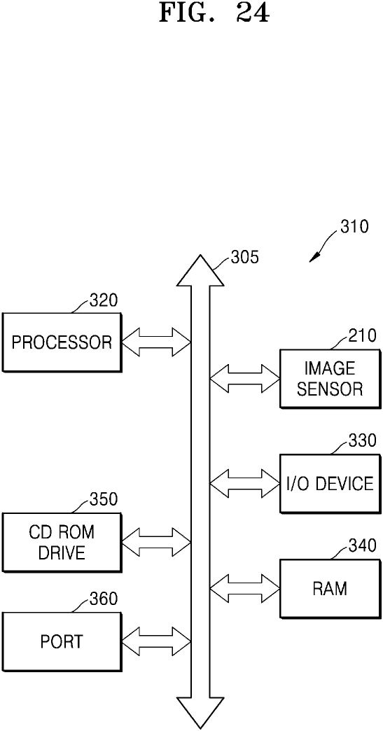

FIG. 23 is a configuration diagram of a camera 230 using an image sensor 210 according to an embodiment of the present inventive concept.

In an embodiment, the camera 230 includes the image sensor 210, an optical system 231 inducing incident light to a light receiving sensor unit of the image sensor 210, a driving circuit 234 driving a shutter device 232 and the image sensor 210, and a signal processing circuit 236 processing an output signal of the image sensor 210.

The image sensor 210 may include at least one of the image sensors 100, 100a, 100b, 100c, 100-3, 100-3a, 100-3b, 100-5, 100-6, 100-7, or 100-8 described above. The optical system 231 including an optical lens forms image light from a subject, such as incident light, on an imaging surface of the image sensor 210. Accordingly, signal charges are accumulated in the image sensor 210 for a certain period of time.

The optical system 231 may be an optical lens system including a plurality of optical lenses. The shutter device 232 controls a light irradiation period and a light blocking period of the image sensor 210. The driving circuit 234 supplies a driving signal to the image sensor 210 and the shutter device 232, controls a signal output operation of the signal processing circuit 236 of the image sensor 210, and controls a shutter operation of the shutter device 232, by the supplied driving signal or a timing signal.

The driving circuit 234 performs a signal transmission operation of the signal processing circuit 236 from the image sensor 210 by supplying the driving signal or the timing signal. The signal processing circuit 236 performs various signal processing on the signal transmitted from the image sensor 210. An image (video) signal on which signal processing is performed is stored in a storage medium such as a memory or output to a monitor.

FIG. 24 is a block diagram of an imaging system 310 including the image sensor 210 according to an embodiment of the present inventive concept.

Specifically, the imaging system 310 is a system that processes an output image of the image sensor 210. The image sensor 210 may include at least one of the image sensors 100, 100a, 100b, 100c, 100-3, 100-3a, 100-3b, 100-5, 100-6, 100-7, or 100-8 described above. The imaging system 300 may be any type of electrical/electronic system in which the image sensor 210 is mounted, such as a computer system, a camera system, a scanner, and an image safety system.

The processor-based imaging system 310, such as a computer system, may include a processor 320, such as a microprocessor or central processing unit (CPU), capable of communicating with an input/output (I/O) device 330 via a bus 305. A CD ROM drive 350, a port 360, and a RAM 340 may be connected to the processor 320 through the bus 305 to exchange data and reproduce an output image with respect to the data of the image sensor 210.

The port 360 may be a port capable of coupling a video card, a sound card, a memory card, a USB device, etc., or communicating data with another system. The image sensor 210 may be integrated together with processors such as a CPU, a digital signal processing device (DSP), or a microprocessor, and may also be integrated with a memory. In some cases, the image sensor 210 may be integrated into a chip separate from the processor. The imaging system 310 may be a system of a camera phone or a digital camera among digital devices.

While the present inventive concept has been particularly shown and described with reference to non-limiting embodiments thereof, it will be understood that various changes in form and details may be made therein without departing from the spirit and scope of the present inventive concept.

What is claimed is:

1. An image sensor comprising:
a first pixel;
a second pixel disposed adj acent to the first pixel;
a pixel separation structure disposed between the first pixel and the second pixel;
a rear anti-reflection layer disposed on the first pixel, the second pixel, and the pixel separation structure; and
a fence structure disposed on the rear anti-reflection layer and positioned to overlap the pixel separation structure in a plan view,
wherein the fence structure comprises a barrier metal layer and a fence, a height of the barrier metal layer is less than a height of the fence, and a width of the barrier metal layer is less than a width of the fence.

2. The image sensor of claim 1, wherein the first pixel and the second pixel include at least one photoelectric conversion element.

3. The image sensor of claim 1, wherein the pixel separation structure includes a conductive layer and an insulating liner, wherein the barrier metal layer is a metal layer that prevents a bruising defect.

4. The image sensor of claim 1, wherein the fence is spaced apart from the rear anti-reflection layer in a thickness direction of the image sensor.

5. The image sensor of claim 1, wherein the fence is an insulator fence or an air fence.

6. The image sensor of claim 1, wherein:
the fence is disposed in direct contact with the rear anti-reflection layer; and
the barrier metal layer is buried in the fence.

7. The image sensor of claim 1, wherein:
the barrier metal layer is a connection type pattern completely surrounding circumferences of the first pixel and the second pixel in the fence planarly; or
the barrier metal layer is a separation type pattern partially surrounding the circumferences of the first pixel and the second pixel in the fence planarly.

8. The image sensor of claim 1, wherein the barrier metal layer is a dot type pattern surrounding circumferences of the first pixel and the second pixel in a dot form in the fence planarly.

9. An image sensor comprising:
a first pixel;
a second pixel disposed adjacent to the first pixel;
a pixel separation structure disposed between the first pixel and the second pixel;
a rear anti-reflection layer disposed on the first pixel, the second pixel, and the pixel separation structure;
a fence structure disposed on the rear anti-reflection layer and positioned to overlap the pixel separation structure in a plan view; and
a color filter disposed at both sides of the fence structure on the rear anti-reflection layer,
wherein the fence structure comprises a barrier metal layer disposed on the rear anti-reflection layer and a fence disposed on the barrier metal layer, wherein a height of the barrier metal layer is less than a height of the fence, a width of the barrier metal layer is less than a width of the fence, and the color filter is buried in an undercut portion recessed inward from both side walls of the fence in a lower portion of the fence.

10. The image sensor of claim 9, wherein the color filter directly contacts the barrier metal layer in the undercut portion of the lower portion of the fence.

11. The image sensor of claim 9, wherein an upper width of the fence is less than a lower width of the fence.

12. The image sensor of claim 9, wherein:
the fence is spaced apart from the rear anti-reflection layer in a thickness direction of the image sensor; and
the barrier metal layer is disposed in a central portion of the fence.

13. The image sensor of claim 9, wherein the pixel separation structure includes a conductive layer and an insulating liner, wherein the barrier metal layer is a metal layer that prevents a bruising defect.

14. The image sensor of claim 9, wherein the fence is an insulator fence or an air fence.

15. The image sensor of claim 9, wherein:
the barrier metal layer is a connection type pattern completely surrounding circumferences of the first pixel and the second pixel in the fence planarly;
the barrier metal layer is a separation type pattern partially surrounding the circumferences of the first pixel and the second pixel in the fence planarly; or
the barrier metal layer is a dot type pattern surrounding the circumferences of the first pixel and the second pixel in a dot form in the fence planarly.

16. An image sensor comprising:
a first pixel;
a second pixel disposed adj acent to the first pixel;
a pixel separation structure disposed between the first pixel and the second pixel;
a rear anti-reflection layer disposed on the first pixel, the second pixel, and the pixel separation structure;
a fence structure disposed on the rear anti-reflection layer and positioned to overlap the pixel separation structure in a plan view; and
a color filter disposed at both sides of the fence structure on the rear anti-reflection layer,
wherein the fence structure comprises a barrier metal layer disposed on the rear anti-reflection layer and a fence disposed on the barrier metal layer, wherein a height of the barrier metal layer is less than a height of the fence, a width of the barrier metal layer is less than a width of the fence, and the barrier metal layer is buried in the fence.

17. The image sensor of claim 16, wherein:
the fence is arranged to completely surround sidewalls and an upper surface of the barrier metal layer, and
the fence is an insulator fence or an air fence.

18. The image sensor of claim 16, wherein:
the fence is disposed in direct contact with the rear anti-reflection layer; and
the barrier metal layer is disposed in a central portion of the fence.

19. The image sensor of claim 16, wherein the pixel separation structure includes a conductive layer and an insulating liner, wherein the barrier metal layer is a metal layer that prevents a brui sing defect.

20. The image sensor of claim 16, wherein:
the barrier metal layer is a connection type pattern completely surrounding circumferences of the first pixel and the second pixel in the fence planarly;
the barrier metal layer is a separation type pattern partially surrounding the circumferences of the first pixel and the second pixel in the fence planarly; or
the barrier metal layer is a dot type pattern surrounding the circumferences of the first pixel and the second pixel in a dot form in the fence planarly.
